(19) United States
(12) Patent Application Publication
(10) Pub. No.: US 2025/0258256 A1
(43) Pub. Date: Aug. 14, 2025

(54) OPTICALLY CONTROLLABLE MESOSCOPIC SPIN ORDER IN SEMICONDUCTORS

(71) Applicant: The University of Chicago, Chicago, IL (US)

(72) Inventors: Alexander A. HIGH, Oakland, MD (US); Kai HAO, Chicago, IL (US); Robert SHREINER, Chicago, IL (US); Andrew KINDSETH, Chicago, IL (US)

(21) Appl. No.: 18/437,560

(22) Filed: Feb. 9, 2024

(51) Int. Cl. G01R 33/20

(52) U.S. Cl. CPC G01R 33/20

(57) ABSTRACT

The disclosure is directed to systems, devices, and methods for generating, stabilizing, and controlling mesoscopic spin order of electrons. The device includes a two-dimensional (2D) semiconductor monolayer configured to accommodate a 2D electron gas; and a first receptacle configured to receive a first optical beam. The first optical beam is configured to interact with the 2D electron gas at a first in-plane spatial position to generate a mesoscopic magnetic/spin state of electrons in the 2D semiconductor monolayer in absence of an external magnetic field. The method includes providing a structure comprising a 2D semiconductor monolayer configured to provide a 2D electron gas; and applying a first optical beam to interact with the 2D electron gas at a first in-plane spatial position to generate a mesoscopic magnetic/spin state of electrons in the 2D semiconductor monolayer in absence of an external magnetic field.

### RELATED APPLICATION

This application is a continuation application of PCT Patent Application No. PCT/US22/40096 Filed on Aug. 11, 2022, which is based on and clams the benefit of priority to U.S. Provisional Application No. 63/231,817 filed on Aug. 11, 2021, both of which are herein incorporated by reference in their entireties.

### GOVERNMENT LICENSE RIGHTS

This invention was made with government support under grant number W911NF-20-1-0217 awarded by Army Research Office. The government has certain rights in the invention.

### BACKGROUND

### 1. Technical Field

The present disclosure relates to methods and devices for controlling, manipulating, and/or regulating spin state of electrons. In particular, the present disclosure relates to methods and devices of using optoelectronic interactions for generating and controlling mesoscopic spin order of electrons in semiconductors.

### 2. Background Information

Spin states of electrons and their associated magnetic properties may be used as building blocks for electro-optical and quantum information storage, processing, and/or computing devices and systems. Various electro-optical and quantum information storage and processing functions may utilize some of the physical properties of electron spins in a solid-state. Such electron spins may be controlled via external electric, magnetic, or optical means.

### SUMMARY

The present disclosure relates to methods, systems, and devices for controlling mesoscopic spin order of electrons in semiconductors.

In one embodiment, the present disclosure describes a device for generating, stabilizing, and controlling mesoscopic spin order of electrons. The device includes a two-dimensional (2D) semiconductor monolayer configured to accommodate a 2D electron gas; and a first receptacle configured to receive a first optical beam. The first optical beam is configured to interact with the 2D electron gas at a first in-plane spatial position to generate a mesoscopic spin state of electrons in the 2D semiconductor monolayer in absence of an external magnetic field.

In another embodiment, the present disclosure describes a method for controlling mesoscopic spin order of electrons. The method includes providing a structure comprising a two-dimensional (2D) semiconductor monolayer configured to provide a 2D electron gas; and applying a first optical beam to interact with the 2D electron gas at a first in-plane spatial position to generate a mesoscopic spin state of electrons in the 2D semiconductor monolayer in absence of an external magnetic field.

In some other embodiments, a system for controlling mesoscopic spin order of electrons may include a memory storing instructions and a processing circuitry in communication with the memory. When the processing circuitry executes the instructions, the processing circuitry is configured to carry out the above methods.

In some other embodiments, a computer-readable medium comprising instructions which, when executed by a computer, cause the computer to carry out the above methods.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The system, device, product, and/or method described below may be better understood with reference to the following drawings and description of non-limiting and non-exhaustive embodiments. The components in the drawings are not necessarily to scale. Emphasis instead is placed upon illustrating the principles of the present disclosure.

FIG. 1A is a schematic diagram of a system for generating, stabilizing, and controlling mesoscopic spin order of electrons.

FIG. 1B is another schematic diagram of a device for generating, stabilizing, and controlling mesoscopic spin order of electrons.

FIG. 1C is a schematic representative diagram of the device for generating, stabilizing, and controlling mesoscopic spin order of electrons in FIG. 1A or FIG. 1B.

FIG. 2A is a schematic diagram of a system for generating, stabilizing, and controlling mesoscopic spin order of electrons.

FIG. 2B is another schematic diagram of a device for generating, stabilizing, and controlling mesoscopic spin order of electrons.

FIG. 2C is another schematic diagram of a device for generating, stabilizing, and controlling mesoscopic spin order of electrons.

FIG. 2D is another schematic diagram of a device for generating, stabilizing, and controlling mesoscopic spin order of electrons.

FIG. 2E is a schematic representative diagram of the device for generating, stabilizing, and controlling mesoscopic spin order of electrons in FIG. 2A, FIG. 2B, FIG. 2C, or FIG. 2D.

FIG. 3A is a flow diagram of a method for generating, stabilizing, and controlling mesoscopic spin order of electrons.

FIG. 3B is a flow diagram of optional steps for the method for generating, stabilizing, and controlling mesoscopic spin order of electrons in FIG. 3A.

FIG. 3C is a flow diagram of optional steps for the method for generating, stabilizing, and controlling mesoscopic spin order of electrons in FIG. 3A.

FIG. 3D is a flow diagram of optional steps for the method for generating, stabilizing, and controlling mesoscopic spin order of electrons in FIG. 3A.

FIGS. 4A-4D describe an exemplary device in various embodiments for generating, stabilizing, and controlling mesoscopic spin order of electrons.

FIGS. 5A-5F describe a spatial profile of spin polarization in various embodiments for optically controlled mesoscopic spin order of electrons.

FIGS. 6A and 6B describe a gate dependence of circular dichroism (CD) spectra in various embodiments for optically controlled mesoscopic spin order of electrons.

FIGS. 7A-7E describe a stability of CD signal in various embodiments for the optically controlled mesoscopic spin order of electrons.

FIGS. 8A and 8B describe an exemplary device fabrication in various embodiments for generating, stabilizing, and controlling mesoscopic spin order of electrons.

FIG. 9 describes an optical setup in various embodiments for generating, stabilizing, and controlling mesoscopic spin order of electrons.

FIG. 10 describe a line shape fitting in various detected spectra in generating, stabilizing, and controlling mesoscopic spin order of electrons.

FIGS. 11A-11C describe another device characterization in various embodiments for generating, stabilizing, and controlling mesoscopic spin order of electrons.

FIGS. 12A-12C describe an exemplary spin polarization dynamics in various embodiments for generating, stabilizing, and controlling mesoscopic spin order of electrons.

FIG. 13 describes another device characterization in various embodiments for generating, stabilizing, and controlling mesoscopic spin order of electrons.

FIG. 14 describes time resolved measurement in various embodiments for generating, stabilizing, and controlling mesoscopic spin order of electrons.

FIGS. 15A-15C describe additional time resolved data in various embodiments for generating, stabilizing, and controlling mesoscopic spin order of electrons.

FIG. 16 describes a chart of pump polarization sweep in various embodiments for generating, stabilizing, and controlling mesoscopic spin order of electrons.

FIGS. 17A and 17B describe characterization of another device in various embodiments for generating, stabilizing, and controlling mesoscopic spin order of electrons.

FIG. 18 shows temperature and gate dependence of CD spatial profiles in various embodiments for generating, stabilizing, and controlling mesoscopic spin order of electrons.

FIGS. 19A and 19B describe power dependence of CD and photoluminescence (PL) amplitudes under different temperatures in various embodiments for generating, stabilizing, and controlling mesoscopic spin order of electrons.

### DETAILED DESCRIPTION OF THE DISCLOSURE

The disclosed systems, devices, and methods will now be described in detail hereinafter with reference to the accompanied drawings that form a part of the present application and show, by way of illustration, examples of specific embodiments. The described systems and methods may, however, be embodied in a variety of different forms and, therefore, the claimed subject matter covered by this disclosure is intended to be construed as not being limited to any of the embodiments. This disclosure may be embodied as methods, devices, components, or systems. Accordingly, embodiments of the disclosed system and methods may, for example, take the form of hardware, software, firmware or any combination thereof.

Throughout the specification and claims, terms may have nuanced meanings suggested or implied in context beyond an explicitly stated meaning. Likewise, the phrase “in one embodiment” or “in some embodiments” as used herein does not necessarily refer to the same embodiment and the phrase “in another embodiment” or “in other embodiments” as used herein does not necessarily refer to a different embodiment. It is intended, for example, that claimed subject matter may include combinations of exemplary embodiments in whole or in part. Moreover, the phrase “in one implementation”, “in another implementation”, or “in some implementations” as used herein does not necessarily refer to the same implementation(s) or different implementation(s). It is intended, for example, that claimed subject matter may include combinations of the disclosed features from the implementations in whole or in part.

In general, terminology may be understood at least in part from usage in context. For example, terms, such as “and”, “or”, or “and/or,” as used herein may include a variety of meanings that may depend at least in part upon the context in which such terms are used. In addition, the term “one or more” or “at least one” as used herein, depending at least in part upon context, may be used to describe any feature, structure, or characteristic in a singular sense or may be used to describe combinations of features, structures or characteristics in a plural sense. Similarly, terms, such as “a”, “an”, or “the”, again, may be understood to convey a singular usage or to convey a plural usage, depending at least in part upon context. In addition, the term “based on” or “determined by” may be understood as not necessarily intended to convey an exclusive set of factors and may, instead, allow for existence of additional factors not necessarily expressly described, again, depending at least in part on context.

The present disclosure relates to methods, systems, and devices for controlling mesoscopic spin order of electrons. In various embodiments, the mesoscopic magnetic/spin state of electrons in two-dimensional (2D) electron gas in a 2D semiconductor monolayer may be maintained, generated, controlled, modified, and/or probed by optical means. While the various implementations focus on electron gas in 2D semiconductors, the underlying principles are not so limited and are applicable to a variety of other material systems.

In various embodiments in the present disclosure, a mesoscopic spin order of electrons may include a mesoscopic magnetism of the electrons; and/or a mesoscopic spin state of electrons may include a mesoscopic magnetic state of the electrons.

In some embodiments, the magnetic/spin state of the electrons may include a ferromagnetic state of the electrons. The magnetic/spin state of the electrons may be used to represent information, for example, 0 or 1 in a classical bit representation, or a quantum superposition state in a quantum bit representation. The magnetic/spin state of the electrons may be used in applications, such as being used as information storage and logic operation devices for quantum computing and quantum information processing.

In some embodiments, optical means may be used to interact with or modify the magnetic/spin state of the electrons, for example, optical pumping may generate a certain magnetic/spin state of the electrons, which can be used to represent information in an optoelectronic component on a photonic integration platform. In some implementations, an optical model may be far-field, wherein the optical receptacle receives a focused optical beam. In other implementations, the optical model may be near-field, wherein the optical receptacle may include an on-chip photonic structure or a waveguide.

In some embodiments, optical means may be used to initiate, control, modify, and/or read a magnetic/spin state of the electrons, enabling optoelectronic-based memory and/or logic gates. Such memory and/or logic gates may be implemented as photonic integrated circuits capable of all optical integration and providing ultrafast networks for information processing. For example, the magnetic/spin state of electrons in the 2D semiconductor monolayer may be used as building blocks for neuromorphic photonic processor and/or neuromorphic optical computing.

In some embodiments, a substantial optical dichroism of magnetic/spin state of the electrons may be used as a basis for detection of such magnetic/spin state using optical means. For example and as described in further detail below, such optical dichroism may lead to polarization-dependent reflectivity of an external optical field. Such polarization-dependent reflectivity may be measured to determine the magnetic/spin state with high-sensitivity. While the various implementations below focus on optical dichroism with respect to circular polarization, the underlying principles described herein are not so limited and are applicable to dichroism of other types of orthogonal polarizations.

The optically-controlled optical dichroism in the systems and devices associated with the magnetic/spin state disclosed herein may be further used in applications such as an optical isolator. As described in further detail below, depending on a polarization state of an optical beam, an optical isolator may allow for transmission of the optical beam in only one direction. Such an optical isolator may be used to prevent unwanted feedback due to backward propagation due to reflection and/or scattering. In some implementations, such an optical isolator may have a memory that is optically-controlled. For example, once the optical isolator is switched on (e.g., by optical pumping), the optical isolator, due to the memory effect, may remain on without continuous pumping.

By way of example, electronic states in two-dimensional (2D) layered materials may exhibit a remarkable variety of correlated phases including Wigner-crystals, Mott insulators, charge density waves, and superconductivity. Ferromagnetic phases of the electronic states and other mesoscopic magnetic/spin states in the 2D layered materials may exist in, for example, electronically-doped transition metal dichalcogenide (TMD) semiconductors.

In various embodiments in the present disclosure, a mesoscopic magnetic/spin state from these material systems at zero external magnetic field may be generated, stabilized, controlled, and detected optically. For example, it may be experimentally demonstrated that mesoscopic ferromagnetic order can be generated and controlled by local optical pumping in monolayer tungsten diselenide (WSe₂), an example of TMD, at zero applied external magnetic field. The generation, stabilization, and control of the mesoscopic magnetic/spin state may be realized by optical pumping. The optical filed used for such optical pumping may be tuned to any wavelength or energy larger than or relative equal to the electron energy bands in the 2D layered material. For example, the optical field may be tuned in the TMD to generate a variety of spin-and valley-polarized magnetic phases at low carrier densities.

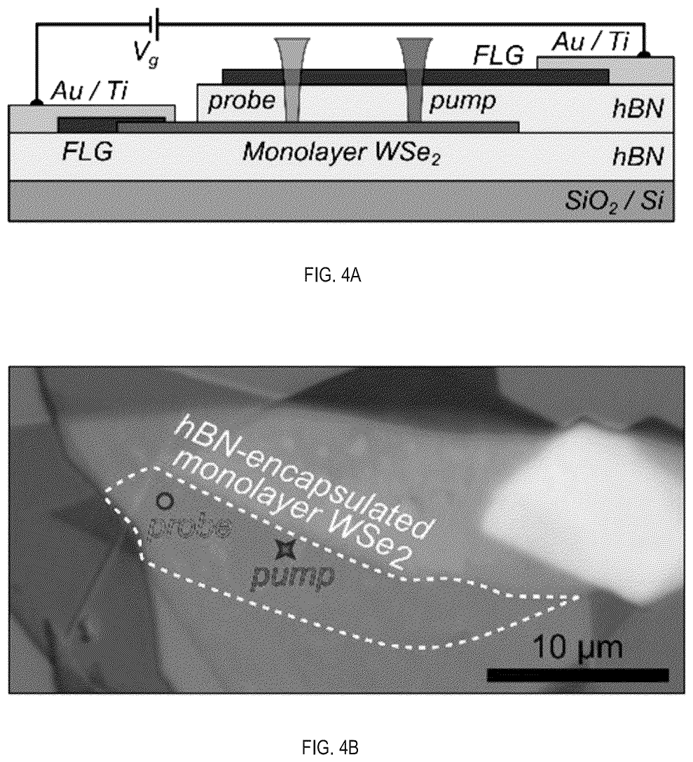

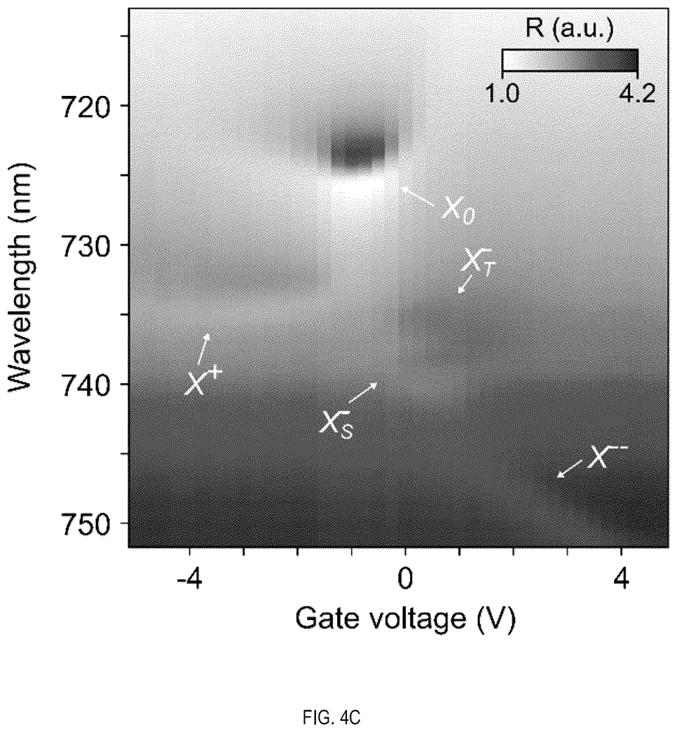

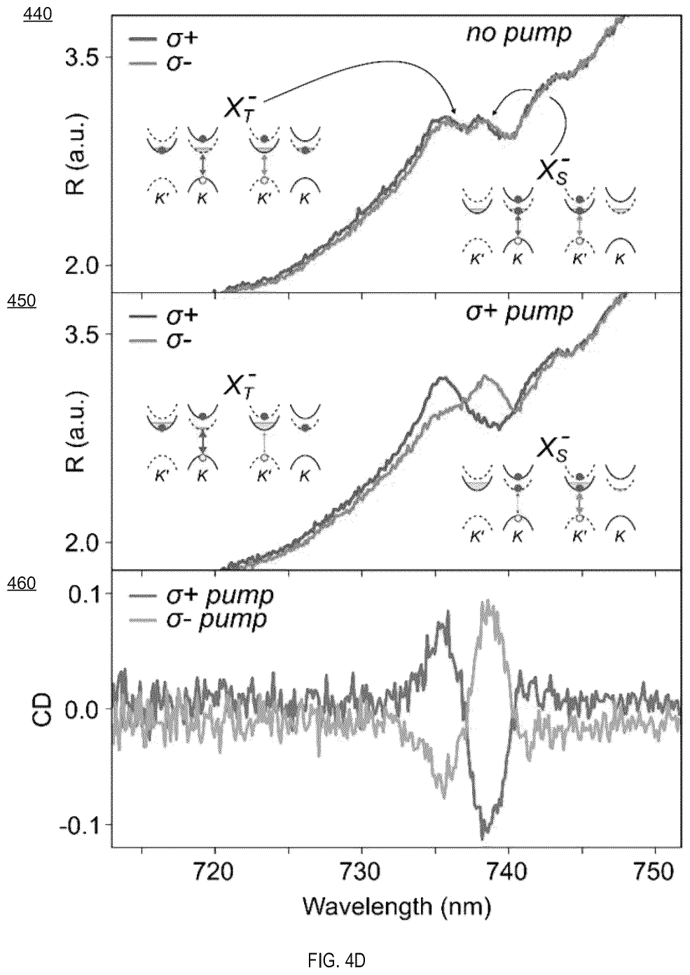

In some implementations, an optical probe may be used for the detection of the mesoscopic magnetic/spin state generated and controlled by optical pumping. Because the mesoscopic magnetic/spin state may be generated and controlled to a spatial extent beyond local optical pumping, the probing optical field may be spatially controlled for the detection of the mesoscopic magnetic/spin state. The detection may be based on measuring the properties of the probing optical field as being affected by the mesoscopic magnetic/spin state. For example, properties of excitons formed in such 2D layer materials may be dependent on the mesoscopic magnetic/spin state and the detection of the mesoscopic magnetic/spin state may be based on the interaction between the optical probing field and the excitons being affected by the mesoscopic magnetic/spin state. Generation of such excitonic states, including charged excitons (trions) may be further controlled by adjusting electric bias field across the 2D electron gas (e.g., as shown below in FIG. 4C).

In an exemplary spatially resolved optical pump-probe implementation, polarization-resolved reflectivity from excitonic states may be used as a probe of a mesoscopic magnetic field reflecting a charge-carrier spin polarization. When a 2D semiconductor device is electron-doped at density nₑ˜10¹² cm⁻², it may be observed that a local, circularly-polarized, microwatt-power optical pump breaks the symmetry between equivalent ferromagnetic spin configurations and creates magnetic order which extends over mesoscopic regions as large as 8 μm×5 μm, bounded by exemplary device edges and folds in the 2D semiconductor. The signature of magnetic order may be observed by detecting a circular dichroism (CD) in reflectivity from the excitonic states. In some implementations, a magnitude exceeding 20% in CD may be observed at resonant exitonic wavelengths.

In some implementations, the helicity of the pump may determine the orientation of the magnetic/spin state, which can be aligned along the two principle out-of-plane axes. In contrast to some observations in 2D materials that have required non-local, slowly varying external magnetic fields to manipulate magnetic phases, the capability to control long-range spin order and corresponding strong polarization dichroism with local and tunable optical pumps without resorting on any external magnetic field is highly versatile.

The present disclosure thus provides new methods and systems based on electron spin and optical technologies and enables sophisticated control of correlated electron phases in two-dimensional electron gases (2DEGs).

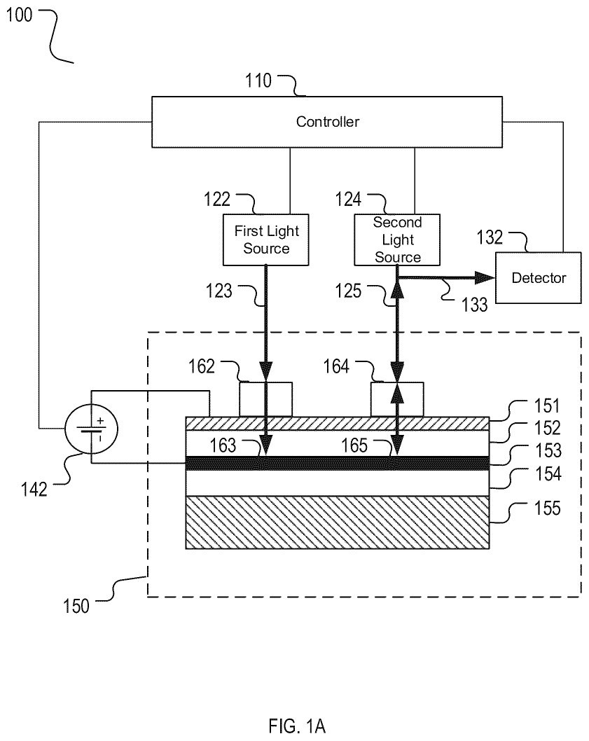

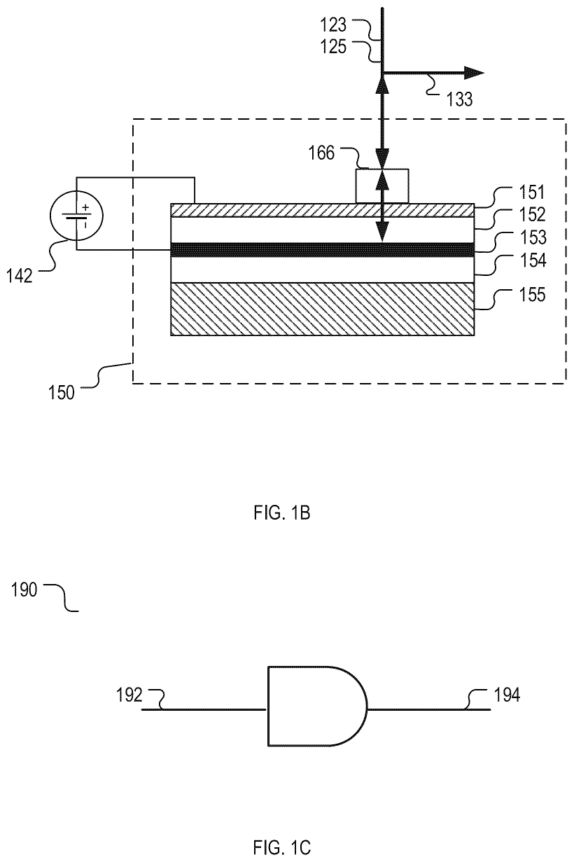

Referring to FIG. 1A, the present disclosure describes various embodiments including a system 100 to be used as a platform for generating, stabilizing, controlling, and detecting mesoscopic spin order of electrons. The system 100 may include any subset or all of the following components: a controller 110, a first light source 122 (alternatively referred to as the first optical source), a second light source 124 (alternatively referred to as the second optical source), a detector 132, a voltage source 142, and/or a device 150. The controller may communicate with the first light source, the second light source, the detector, the voltage source, and/or the device. The communication of the controller may include sending commands to at least one component, sending data to at least one component, and/or receiving data from at least one component.

The controller 110 may be any form of mobile or fixed electronic devices including but not limited to desktop personal computer, laptop computers, tablets, mobile phones, personal digital assistants, and the like. The controller 110 may be implemented as a general-purpose computer or a dedicated electronic controller. The controller 110 may be installed with a user interface for accessing one or more components in the system. The controller 110 may include communication interfaces, a processor, input/output (I/O) interfaces, storages, and display circuitry. The controller 110 may communicate with all other components of the system to send/receive commands, data, or the like. The controller 110 may be optional in the system 100.

The first light source 122 and/or the second light source 124 may be arc lamps, light emitting diodes (LEDs), or laser sources. The light/optical sources may operate in either a pulsed mode or a continuous wave (CW) mode. A light/optical source may produce one or more optical beams to interact with the device 150 at different controllable time points or simultaneously. The one or more optical beams may propagate in free space, optical fibers, planar optical waveguides and cavities, or a combination of free space, optical fibers, and planar optical waveguides and cavities. The one or more optical beams may be further processed by one or more optical components, for example but not limited to, mirrors, lenses, prism, gratings, and objectives of confocal microscope. The one or more optical beams may focus onto a particular region/position of the device. The one or more optical beams may be applied to a same or different region of the device. The produced one or more optical beams may scan across different regions of the device 150 so that the produced one or more optical beams may interact with different regions/positions of the device 150 simultaneously or in a sequential manner. The first light source 122 and/or the second light source 124 may be optional in the system 100.

When the first light source is a CW light source, the first light source may generate a steady-state of mesoscopic magnetic/spin state of electrons in 2D gas in a 2D semiconductor monolayer. When the first light source is a pulsed light source, the first light source may inject a spin polarization to mesoscopic magnetic/spin state of electrons in 2D electron gas in a 2D semiconductor monolayer.

The detector 132 may include an optical detector, for example but not limited to, a single-photon detector, a photodiode, an avalanche photodiode (APD), a photomultiplier tube (PMT), a spectrometer, a charge-coupled device (CCD) image sensor, or a complementary metal-oxide semiconductor (CMOS) image sensors. The detector 132 may further include one or more optical filters to select and detect optical photons with a certain energy. For example, the one or more optical filters may include but are not limited to a long pass filter, a short pass filter, a band pass filter, a monochromatic filter, and a dichroic filter. The detector 132 may further include a memory storing instructions and data, and one or more processor in communication with the memory to perform functions related to optical measurement and data processing. The detector 132 may be optional in the system 100.

The voltage source 142 may be a device to generate an alternate current (A.C.) or direct current (D.C.) voltage. The voltage source 142 may be controlled by the controller 110 to generate time independent or time varying external voltages or electric field in the device 150. The voltage source 142 may be optional in the system 100.

In various embodiments, the device 150 may include a subset or all of the following components: a gate layer 151, a top layer 152, a semiconductor monolayer 153, a bottom layer 154, and/or a substrate layer 155. The device 150 may include a 2D electron gas in the 2D semiconductor monolayer 153.

In some implementations, the top layer 152 and the bottom layer 154 may be configured to sandwich or encapsulate the 2D semiconductor monolayer 153.

In some implementations, the gate layer 151 may include an electrically conductive layer disposed on the top layer and configured to generate an electrical field across the 2D semiconductor monolayer 153. The electrically conductive gate layer 151 may be electrically biased by the voltage source 142 to control a density of the 2D electron gas. To generate electric bias in the 2D electron gas, the 2D semiconductor monolayer 153 may be connected electrically to the voltage source 142. The connection may be realized via gate structures (not illustrated in FIG. 1A) in electric contact with the 2D electron gas in the 2D monolayer.

In some embodiments, the 2D semiconductor monolayer 153 may include, merely as an example, a tungsten diselenide (WSe2) monolayer; the top layer may include a hexagonal boron nitride (hBN) layer; the bottom layer may include a hBN layer; and/or the electrically conductive layer may include a few-layer graphene (FLG). Any other 2D monolayer structures may be used.

The device 150 may further include a first receptacle 162 and/or a second receptacle 164. The first receptacle 162 may be configured to receive a first optical beam 123 from the first light source 122. The second receptacle 164 may be configured to receive a second optical beam 125 from the second light source 124. In another implementation, the first receptacle and the second receptacle may receive an optical beam from a same light source.

In one implementation, the first receptacle 162 and/or the second receptacle 164 may comprise an optical coupling device, for example but not limited to, an optical fiber coupler, a lens, a mirror, a transparent window, and the like. In another implementation, the first receptacle and/or the second receptacle may comprise no particular structure, and solely provide a means for an optical beam to propagate onto the 2D semiconductor monolayer. For example, the first optical beam 123 and the second optical beam 125 may be coupled into the device 150 via free-space coupling and in such cases, the receptacle may not be needed.

The first optical beam 123 is configured to interact with the 2D electron gas at a first in-plane spatial position 163, which may generate a mesoscopic magnetic/spin state of electrons in the 2D semiconductor monolayer in absence of an external magnetic field.

In another implementation, the second receptacle 164 may be configured to receive a second optical beam 125 from the second light source 124, and the second optical beam 125 may be configured to probe the mesoscopic magnetic/spin state of the electrons in the 2D electron gas at a second in-plane spatial position 165. For example, the second optical beam 125 may be reflected to generate a reflected optical beam 133. The first in-plane spatial position may be at a different position from the second in-plane spatial position. For example, the first in-plane spatial position may be at a distance away from the second in-plane spatial position. As an example, the distance may be in a range between 0.1 and 1000 micrometers (μm). The reflected optical beam 133 from the 2D electron gas may be configured to pass through an output port configured to direct the reflected optical beam 133 to an optical detector.

In some implementations, the reflected optical beam 133 may propagate back through the second receptacle 164 as shown in FIG. 1A, and propagate onto the optical detector 132. The optical detector is configured to measure the reflected optical beam so as to detect a reflectivity of the 2D electron gas.

In some implementations, the first optical beam may be tuned to a first energy larger than a bandgap of the 2D semiconductor monolayer; and the second optical beam may be tuned to a second energy resonant with at least one of a excitonic state, a singlet trion state, or a triplet trion state of the 2D electron gas. Merely as an example and for the 2D WSe₂ structure above, the first energy may correspond to a wavelength of about 660 nanometer (nm), and the second energy may correspond to a wavelength of about 735 nm. Here, “about” a wavelength may refer to a range of ±5 nm of the wavelength.

In some implementations, the first optical beam may be configured in a first polarized state, for example but not limited to, a left circular polarized state, a right circular polarized state, or a linear polarized state. In one particular implementation, the first polarized state may be a left circular polarized state.

The first optical beam in the first polarized state may interact with the 2D electron gas to generate a first ferromagnetic state of electrons in the 2D electron gas at the first position in the 2D semiconductor monolayer. The first ferromagnetic state of electrons may transport to other locations in the 2D semiconductor monolayer via, for example, long range electron-electron interactions.

The second optical beam may be tuned in the first polarized state, and the optical detector may detect the reflected optical beam to obtain a first reflectivity. The second optical beam may be also tuned in a second polarized state, which is orthogonal to the first polarized state, and the optical detector may detect the reflected optical beam to obtain a second reflectivity. For example, because the first polarized state is orthogonal to the second polarized state, when the first polarized state is a left circular polarized state, the second polarized state is the right circular polarized state; and when the first polarized state is a right circular polarized state, the second polarized state is a left circular polarized state.

The controller may obtain the first reflectivity and the second reflectivity, and calculate the polarization dichroism, e.g., circular dichroism (CD), as a measure of the mesoscopic magnetic/spin state of the electrons in the 2D semiconductor monolayer based on the first reflectivity and the second reflectivity.

In various embodiments, referring to FIG. 1B, a device 150 may include a single receptacle 166. The receptacle 166 may receive a first optical beam 123 and a second optical beam 125, and also output a reflected optical beam 133.

In various embodiments, referring to FIG. 1C, a device 150 may be schematically represented as a gate device 190 with an input 192 and an output 194. The input 192 may be a “write” or “initialize” input, which may correspond to the first optical beam to interact with the gate device 190 to set the gate device 190 in a desired magnetic/spin state of electrons in the 2D semiconductor monolayer. The output 194 may be a “read” or “probe” output, which may correspond to the reflected optical beam of the second optical beam so as to probe the magnetic/spin state of the electrons in the 2D semiconductor monolayer.

In various embodiments, a system 100 may include the capability of using a third optical beam to further interact with a 2D electron gas so as to modify a mesoscopic magnetic/spin state of electrons in a 2D semiconductor monolayer.

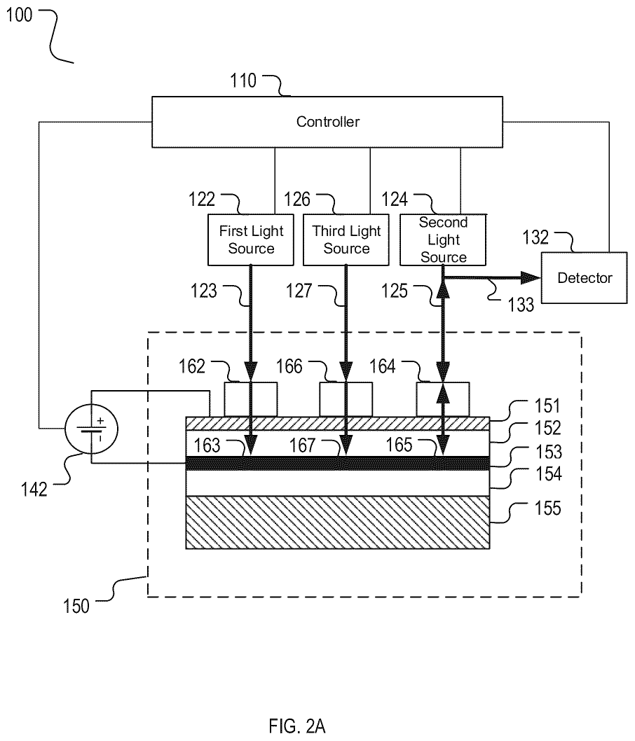

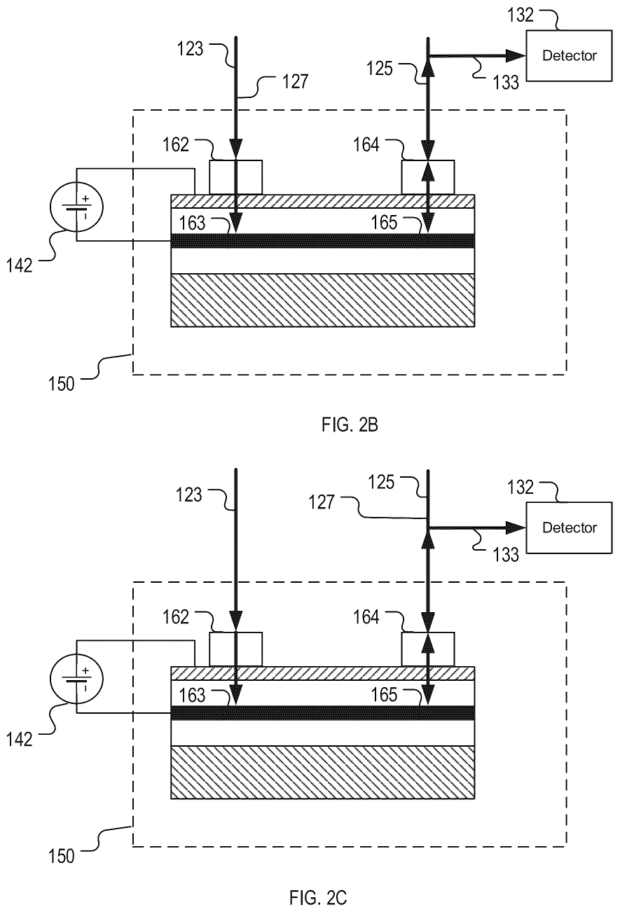

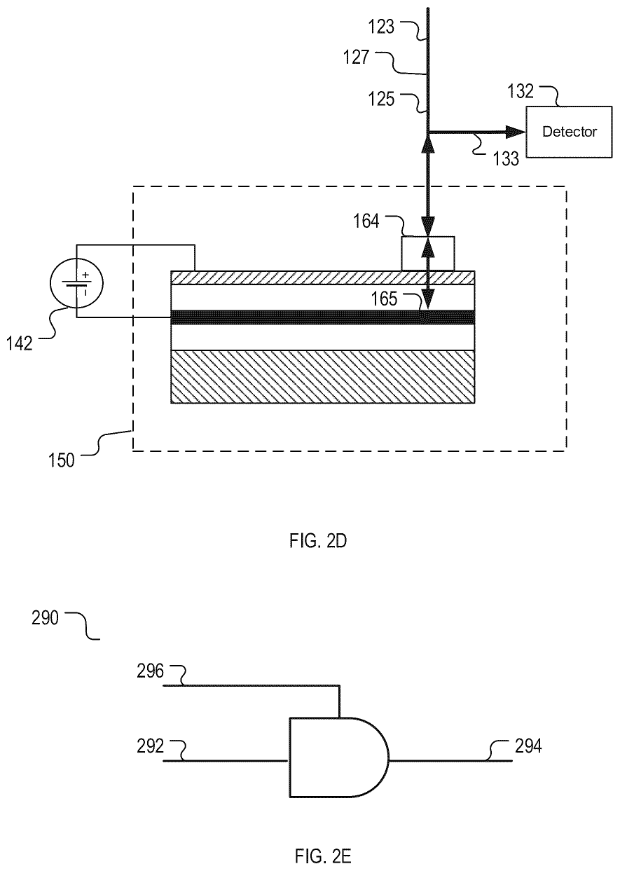

As an example and referring to FIG. 2A, the system 100 may further include a third light source 126 providing a third optical beam 127. The third light source 126 may controlled by the controller 110. In some implementations, the third optical beam 127 may be output from a same light source as either a first light source 122 or a second light source 124.

Referring to FIG. 2A, the device 150 may further include a third receptacle 166 to receive the third optical beam, and the third optical beam may interact with the 2D electron gas at a third in-plane position 167. In some implementations, the third in-plane position 167 may be different from either the first in-place position or the second in-plane position. In another implementation, as discussed below, the third in-plane position 167 may be a same position as either the first in-place position or the second in-plane position.

In some implementations, the third optical beam may be applied after the first optical beam in a time sequence, so that the third optical beam may modify the magnetic/spin state of the electrons generated by the first optical beam; and/or the third optical beam may be applied before the second optical beam in time so that the second optical beam may probe a modified magnetic/spin state of the electrons due to the third optical beam.

In some implementations, referring to FIG. 2B, the third receptacle may be a same receptacle as the first receptacle 162 so that the third optical beam 127 shares the same optical path as the first optical beam 123, so that the third optical beam 127 interacts with the 2D electron gas at a first in-plane position 163.

In some implementations, referring to FIG. 2C, the third receptacle may be a same receptacle as the second receptacle 164 so that the third optical beam 127 shares the same optical path as the second optical beam 125, so that the third optical beam 127 interacts with the 2D electron gas at a second in-plane position 165.

In some implementations, referring to FIG. 2D, the first receptacle, the second receptacle, and the third receptacle may all be the same receptacle 164 so that the first optical beam, the second optical beam 125, and the third optical beam 127 shares a same optical path entering into the device 150, and so that the first optical beam 123, the second optical beam 125, and the third optical beam 127 interacts with the 2D electron gas at a same in-plane position 165. The reflected optical beam 133 corresponding to the second optical beam 125 may be output from the receptacle 164 to a detector 132.

In various embodiments, referring to FIG. 2E, a device 150 may be schematically represented as a logic gate device 290 with an input 292, a control input 296, and an output 294. The input 292 may be a “write” or “initialize” input, which may correspond to the first optical beam to interact with the logic gate device 290 to set the logic gate device in a desired magnetic/spin state of electrons in the 2D semiconductor monolayer. The control input 296 may be a “control” or “modify” input, which may correspond to the third optical beam to interact with the logic gate device 290 to modify the magnetic/spin state generated by the input 292. The output 294 may be a “read” or “probe” output, which may correspond to the reflected optical beam based on the second optical beam so as to probe the modified magnetic/spin state of the electrons by the control input 296.

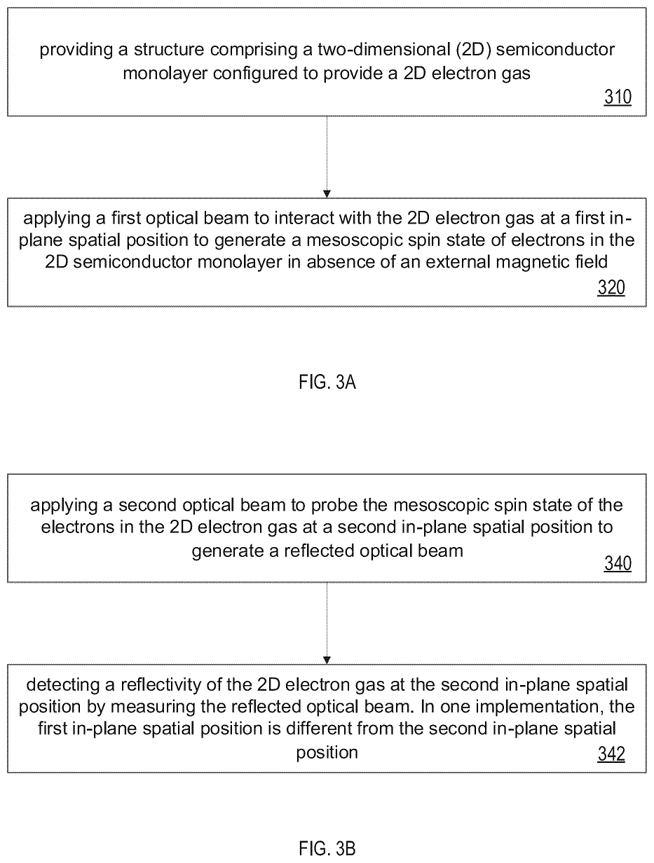

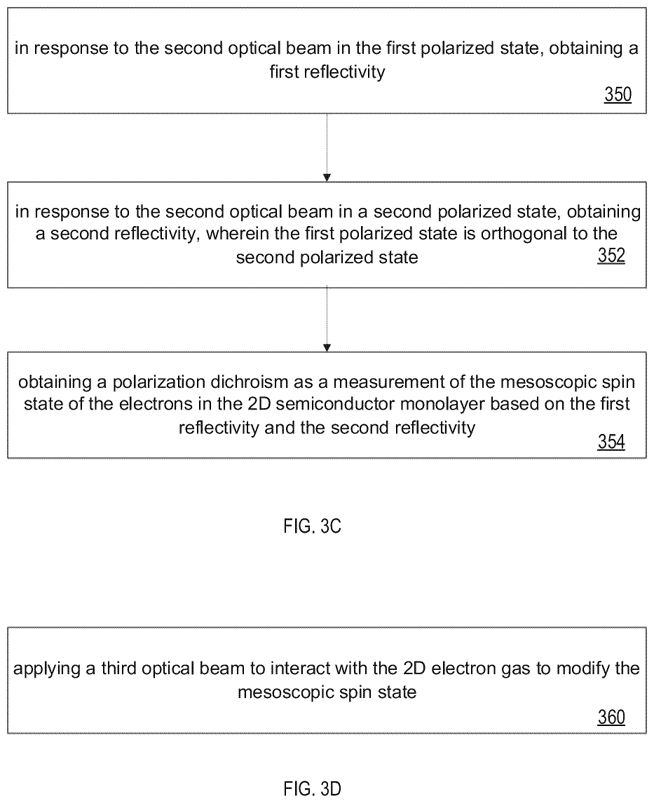

In various embodiments, FIG. 3A shows a flow diagram of a method 300 for controlling mesoscopic spin order of electrons. The method 300 may be performed in any embodiment or a combination of more than one embodiment described in the present disclosure. The method 300 includes a subset or all of the following steps. Step 310: providing a structure comprising a two-dimensional (2D) semiconductor monolayer configured to provide a 2D electron gas. Step 320: applying a first optical beam to interact with the 2D electron gas at a first in-plane spatial position to generate a mesoscopic magnetic/spin state of electrons in the 2D semiconductor monolayer in absence of an external magnetic field.

In some embodiments, referring to FIG. 3B, the method 300 may optionally further include a subset or all of the following steps. Step 340: applying a second optical beam to probe the mesoscopic magnetic/spin state of the electrons in the 2D electron gas at a second in-plane spatial position to probe the mesoscopic magnetic field. For example, the detection may be based on measuring a reflected optical beam of the second optical beam. Step 342: detecting, for example, a reflectivity of the 2D electron gas at the second in-plane spatial position by measuring the reflected optical beam. In one implementation, the first in-plane spatial position is different from the second in-plane spatial position.

In some implementations, the first optical beam is tuned to a first energy larger than a bandgap of the 2D semiconductor monolayer; and the second optical beam is tuned to a second energy resonant with at least one of a excitonic state, a singlet trion state, or a triplet trion state of the 2D electron gas.

In other implementation, polarization of the first optical beam is controlled. The polarization of the first optical beam is configured in a first polarized state.

In some embodiments, referring to FIG. 3C, the method 300 may optionally further include a subset or all of the following steps. Step 350: in response to the second optical beam in the first polarized state, obtaining a first detection. The first detection may include reflectivity of the second optical beam in the first polarization state. Step 352: in response to the second optical beam in a second polarized state, obtaining a second detection. The second detection may include reflectivity of the second optical beam in the second polarization state. The first polarized state may be orthogonal to the second polarized state. For example, the first polarization state may be a first circular polarization state and the second polarization may be a second circular polarization state orthogonal to the first circular polarization state. Step 354: obtaining a polarization dichroism as a measurement of the mesoscopic magnetic/spin state of the electrons in the 2D semiconductor monolayer based on the first reflectivity and the second reflectivity. For example, the polarization dichroism may include a circular dichroism.

In one implementation, the first polarized state may be a left circular polarized state; and the second polarized state may be a right circular polarized state.

In some implementations, the structure comprises: a top layer and a bottom layer encapsulating the 2D semiconductor monolayer; and an electrically conductive layer disposed on the top layer and configured to generate an electrical field across the 2D semiconductor monolayer.

In another implementation, the 2D semiconductor monolayer comprises a tungsten diselenide (WSe2) monolayer; the top layer comprises a hexagonal boron nitride (hBN) layer; the bottom layer comprises a hBN layer; and the electrically conductive layer comprises a few-layer graphene (FLG).

In another implementation, the electrically conductive layer is electrically biased to control a density of the 2D electron gas.

In some embodiments, referring to FIG. 3D, the method 300 may optionally further include the following step. Step 360: applying a third optical beam to interact with the 2D electron gas to modify the mesoscopic magnetic/spin state.

Below, the present disclosure also describes at least one example in details. The at least one example may serve as additional or alternative embodiments, but not as limitations to the embodiments/implementations described above.

### Spin Polarization in 2DEGs

Due to favorable material properties and tuning capabilities, TMDs have become a rapidly emerging platform for the study and manipulation of collective phases in 2DEGs. For free electrons in TMDs, the combination of a large effective mass ˜0.44 mₑ and reduced dielectric screening creates a Bohr-radius that is only slightly larger than the lattice constant. As a result, the energy of Coulombic interactions can be appreciably larger than energies associated with phase-space filling, leading to collective ordering of electronic states dictated by long-range exchange interactions. In particular, exchange interactions are predicted to create a variety of spin-and valley-polarized magnetic phases at low carrier densities n˜10¹²-10¹³ cm⁻². These carrier densities are readily achievable in TMDs by electrostatic doping.

It may be shown that under applied external magnetic field and in certain doping regimes, electrons in molybdenum disulphide (MoS₂) and molybdenum diselenide (MoSe₂) exhibit magnetic order with near-complete spin-polarization far beyond the predictions of a simple thermal population model. The spin polarization manifests as circular dichroism in reflectivity and photoluminescence measurements of the excitonic states, and was initially attributed to an interaction-enhanced electronic g-factor (so-called giant paramagnetism) or the emergence of ferromagnetic order. In the ferromagnetism model, the spin polarization is due to strong exchange interactions which favor the formation of a spin-polarized state in both the K and K′ valleys. It may be demonstrated that the system transitions from a ferromagnetic to a paramagnetic phase with increased doping, suggesting direct electronic control over the electron-electron interactions and correlated phases. The compelling evidence may show that the magnetic ordering at moderate carrier densities is ferromagnetic in nature and that spin-polarized electronic states should persist even at zero magnetic field. Some embodiments in the present disclosure show that ferromagnetic order could be generated and stabilized at zero applied magnetic field, and/or net magnetization or spin polarization may be observed, which may be attributed to a global symmetry breaking mechanism.

Optical pumping may be used to break the symmetry between equivalent spin configurations in TMDs. Pumping of individual monolayers or heterostructures of TMDs with circularly polarized light may generate spin imbalances with microsecond-long relaxation times. For WSe₂ monolayers in the electron doped region, resident electrons may be dynamically spin/valley-polarized by continuous pumping with circular light. Photo-generated electrons excited in a selected valley by the circularly polarized pump may preferentially relax to the opposite valley due to fast spin-conserving intervalley scattering. Additionally, the intravalley recombination of resident electrons with photo-generated holes forming dark excitons can enhance the asymmetry of the valley populations. The resulting spin-polarization is maintained in the presence of the continuous pump as these processes occur on timescales faster than the spin relaxation rate. Moreover, due to the relatively low free charge carrier densities n≈10¹²-10¹³ cm⁻², a significant population of resident carriers may be spin-polarized, potentially sufficient to break the symmetry between ground-state spin configurations and stabilize the ferromagnetic order.

### Mesoscopic Magnetic/spin State Generation and Detection in 2DEGs

The present disclosure further describes, as an example, the impact of above-bandgap, circularly polarized optical pumping on h-BN encapsulated monolayers of WSe₂. The heterostructure layout and optical image of the exemplary device (D1) are presented in FIG. 4A and FIG. 4B. The doping level in the monolayer WSe₂ can be controlled by applying gate voltage between the few-layer graphene (FLG) contact and top Au/Ti gate and manifests in the appearance of neutral and charged excitonic resonances in the reflection spectra, as shown in FIG. 4C. For low temperature measurements at T=4 K within the moderately electron-doped region, singlet (X⁻_{S}) and triplet (X⁻_{T}) trions are clearly observed. Reflection from a circularly polarized supercontinuum laser provides a probe of the local, valley-selective optical response. In the absence of pumping, balanced reflection of σ+ and σ− polarized light is observed (440 in FIG. 4D), indicating that the probe laser does not generate any symmetry breaking. Next, the exemplary device is pumped with a 660 nm diffraction-limited continuous wave laser with a spot diameter of 500 nm and a power of 7.8 μW. To demonstrate the nonlocality of pump-induced effects and to eliminate the influence of photoluminescence in detection, the probe spot is separated by nearly 8 μm from the pump (FIG. 4B). The reflection spectra of the σ+ and the σ+ polarized probe under σ₊ polarized pumping are markedly different—the triplet (singlet) trion dominates the probe signal co(cross)-polarized to the pump (see 450 in FIG. 4D). This pump-induced circular dichroism (CD) is characterized by CD=ΔR⁺−ΔR⁻, where ΔR^{+,-}=(R^{+,-}ₒₙ/R^{+,-}_{off})−1 is the differential reflectivity comparing the σ+,− probed reflection in the presence (R^{+,-}ₒₙ) and absence (R^{+,-}_{off}) of the pump. The CD signal displays amplitudes approaching 10% and inverts with the sign of the pump polarization (460 in FIG. 4D).

The CD is a direct signature of electron spin/valley-polarization, in which singlet and triplet trions are formed preferably in the opposite valleys (see 450 in FIG. 4D). To quantify the spin polarization, the valley-dependent oscillator strengths of the trion states may be determined by fitting the reflection contrast with a Breit-Wigner-Fano lineshape. Since the valley-dependent charge density correlates with the oscillator strength of the transition, it may be estimated that 90% (10%) of charges reside in the valley cross(co)-polarized with the pump even at 8 μm pump-probe separation. This corresponds to a spin polarization Pₛ=0.77, where Pₛ=(A⁺−A⁻)/(A⁺+A⁻) and A^{+,-} is the probe-polarization-selective oscillator strength of the trion state under optical pumping. For an electron doping density of n≈1.8×10¹² cm⁻², this yields a spin population imbalance of ˜1.4×10⁴ μm⁻². Small disparities in the local optical environment and device inhomogeneity may subtly modify the relationship between the CD signal and the underlying spin polarization, however, this extracted value provides a reasonable approximation.

FIGS. 4A-4D shows an exemplary device in various embodiments. FIG. 4A includes schematic of hBN-encapsulated WSe₂ monolayer with few-layer graphene top gate and contacts. The optical pump and probe are spatially separated. FIG. 4B includes optical microscope image of an exemplary device (D1). FIG. 4C includes gate dependent reflection spectra of the WSe₂ exemplary device. The excitonic resonance features are labeled correspondingly. 440 in FIG. 4D includes σ+ and σ− reflection spectra at 0.5 V, where the singlet and triplet trion features are well resolved. Inset: Singlet and triplet trion configurations showing balanced valley populations. 450 in FIG. 4D includes σ+ and σ− reflection spectra at 0.5 V under σ+ pumping. Insert: Schematic of singlet and triplet trion in optically pumped spin/valley-polarized electron bath. 460 in FIG. 4D includes circular dichroism (CD) spectra under σ+ and σ− pumping. T=4 K and pump power is 7.8 μW.

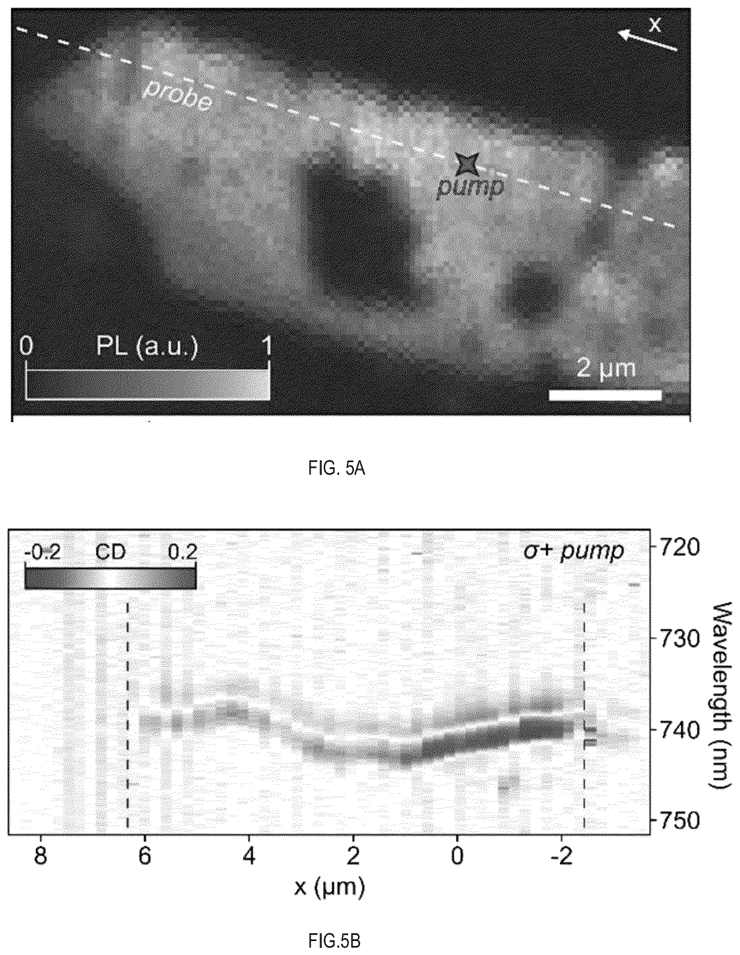

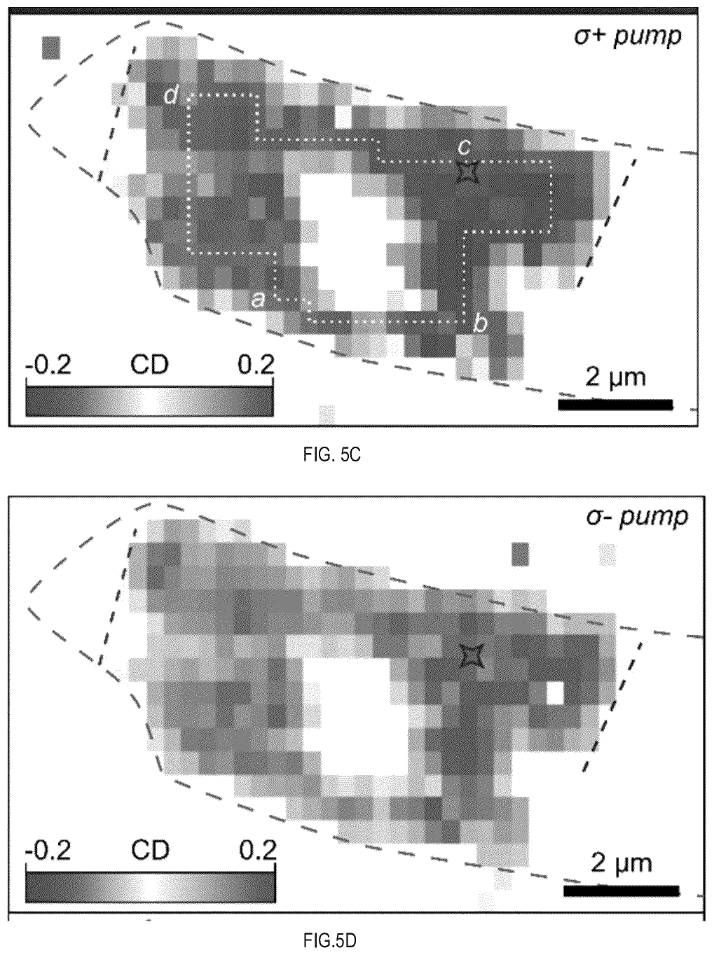

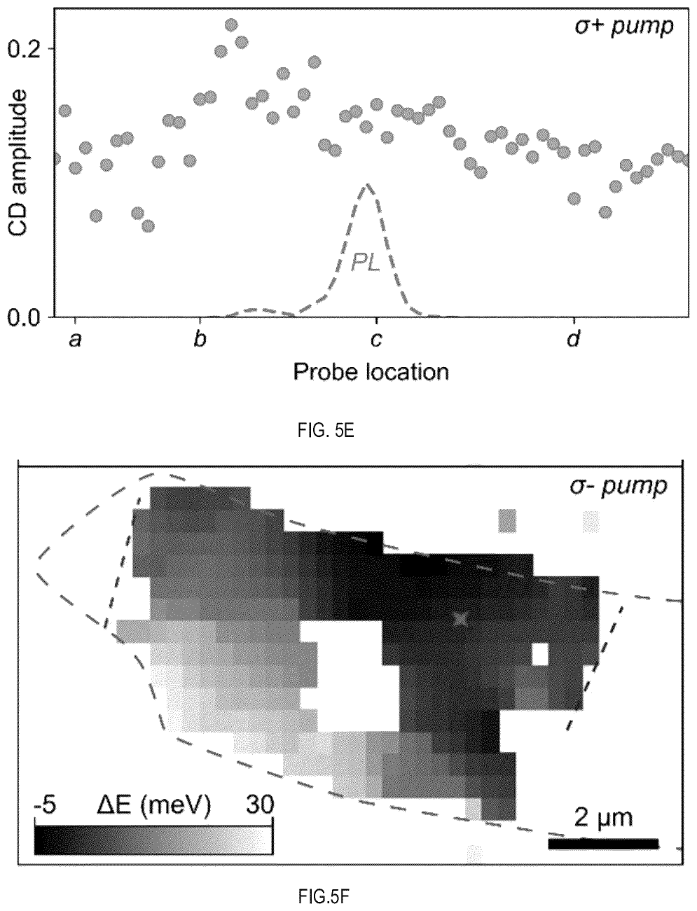

Remarkably, the optical pump generates a near-complete spin polarization that persists micrometers away from the pump location. The present disclosure also describes this spatial dependence in more detail. FIG. 5A shows a photoluminescence (PL) map of the region of interest (ROI) of the monolayer flake. The central dark area corresponds to a bilayer region. Keeping the pump at the fixed-point x=0 μm (star in FIG. 5A), the probe is scanned along the length of the monolayer (dashed line in FIG. 5A). Strong CD signal is detected, reaching an amplitude of 20% (FIG. 5B). Moreover, the CD signal shows significant energetic variation, indicating that the spin polarization is robust to device inhomogeneity. These observations imply the maintenance of long-range spin polarization built up under circularly polarized optical pumping.

To further characterize the spatial profile of the spin polarization, the CD signal across the entirety of the ROI may be mapped. FIG. 5C depicts the CD associated with the singlet trion peak as the probe is scanned across the flake while the σ+ pump remains fixed. CD is clearly observed within the pristine portion of the ROI, except for in the bilayer region where no resonance peak nor CD signal are found. When the sign of the pump polarization is flipped to σ− (FIG. 5D), the CD signal inverts everywhere. To investigate the correlation between the pump-probe displacement and the CD intensity, a cross section of the CD amplitude around the ROI (FIG. 5E) may be plotted. No clear CD signal decay is observed as the separation increases. Indeed, in the c to b direction, an increase in CD signal may be observed. The spatial inhomogeneity of the exemplary device is depicted in FIG. 5F. The trion resonance energy varies by up to 30 meV within the ROI, while the CD signal is still robust. However, more prominent imperfections apparently destroy the spin polarization. The purple and blue dashed lines indicate wrinkles and residue in the heterostructure observed under microscope imaging, which correspond to observable dips in photoluminescence (FIG. 5A). The CD signal terminates upon crossing the noted defects.

FIGS. 5A-5F shows spatial profile of the spin polarization. FIG. 5A includes photoluminescence (PL) map of the ROI. FIG. 5B includes spatially dependent CD spectra under σ+ pumping. The fixed pump location x=0 μm is given by the star in FIG. 5A, while the probe is scanned along the dashed white line in FIG. 5A. FIG. 5C and FIG. 5D include maps of the CD amplitude across the whole ROI under σ+ (FIG. 5C) and σ− (FIG. 5D) pumping. FIG. 5E includes CD amplitude along the dashed contour in FIG. 5C. Dashed gray line depicts the PL intensity for fixed-position pumping. FIG. 5F include map of peak energy shifts of the singlet CD signal compared to the value at the pump location. Purple and blue dashed lines correspond to wrinkles on the exemplary device. T=4 K and pump power is 7.8 μW.

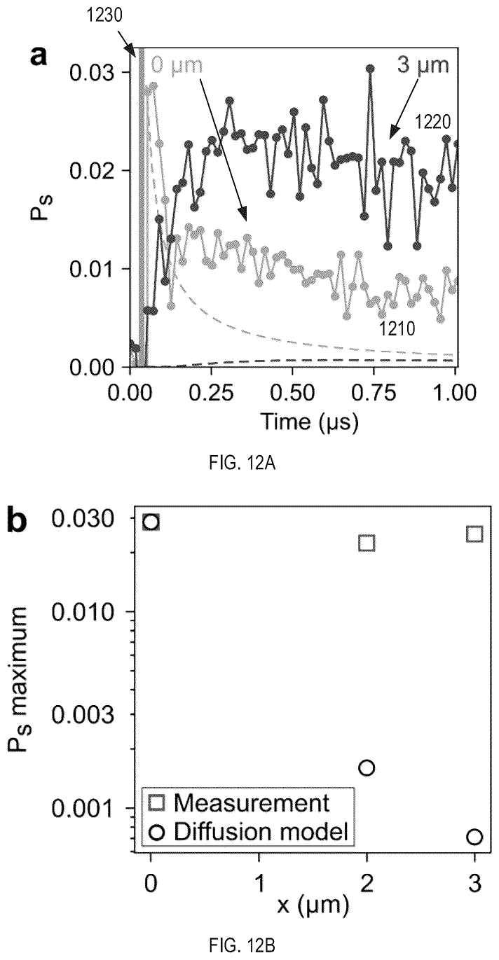

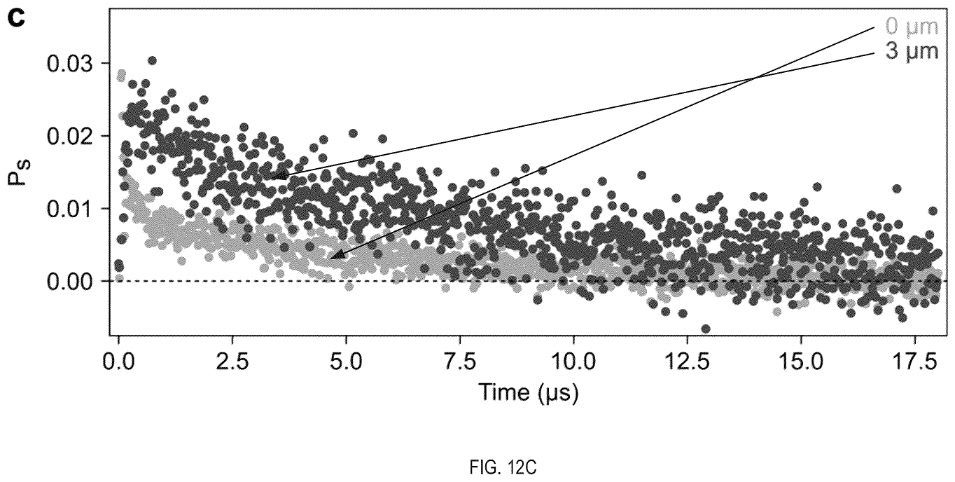

The temporal dynamics of the spin polarization may be investigated with different pump/probe separations (e.g., on a second sample). A local, 5 ns pulsed laser at 633 nm may be used to generate a spin imbalance under the pump and then spatially- and temporally-resolved changes to the spin polarization extracted from differential reflection may be measured. As the system evolves in time, mesoscopic spin polarization emerges at micron length scales over a microsecond timescale (FIG. 12A). The peak spin polarization observed exhibits no systematic change with increasing pump/probe separation (FIG. 12B, squares), agreeing with the spatially uniform CD under CW pumping. The spin polarization at the pump location sets an upper bound for the optical spin polarization injection. After building up for hundreds of nanoseconds, the spin polarization detected away from the pump location exceeds that observed at the pump location. These results cannot be captured by a two-dimensional diffusion-decay model with pulsed excitation, which predicts at least an order of magnitude decay in polarization at three-micron separation regardless of the parameter estimates used for the carrier diffusion constant and relaxation time. These results indicate that after the spin injection from the initial excitation pulse, the spin polarization is appreciably amplified across the sample and persists for over 10 μs (FIG. 12C).

FIGS. 12A-12C describe the spin polarization dynamics. FIG. 12A shows a time-resolved spin polarization extracted from changes in reflection probed overlapping (1210) and 3 μm (1220) from a pulsed circular pump with average power of 2 nW at a repetition rate of 50 kHz. Grey bar (1230) corresponds to the window of the pulsed pump. Dashed lines indicate the predicted profiles of a diffusion-decay model. FIG. 12B shows comparison of the maximum spin polarization as a function of pump-probe offset between the measured values and the simulated values of the diffusion-decay model. FIG. 12C shows the extended dynamics of the time-resolved spin polarization, wherein the temperature (T)=4 K and gate voltage is 0.5 V (nₑ˜2×10¹² cm⁻²).

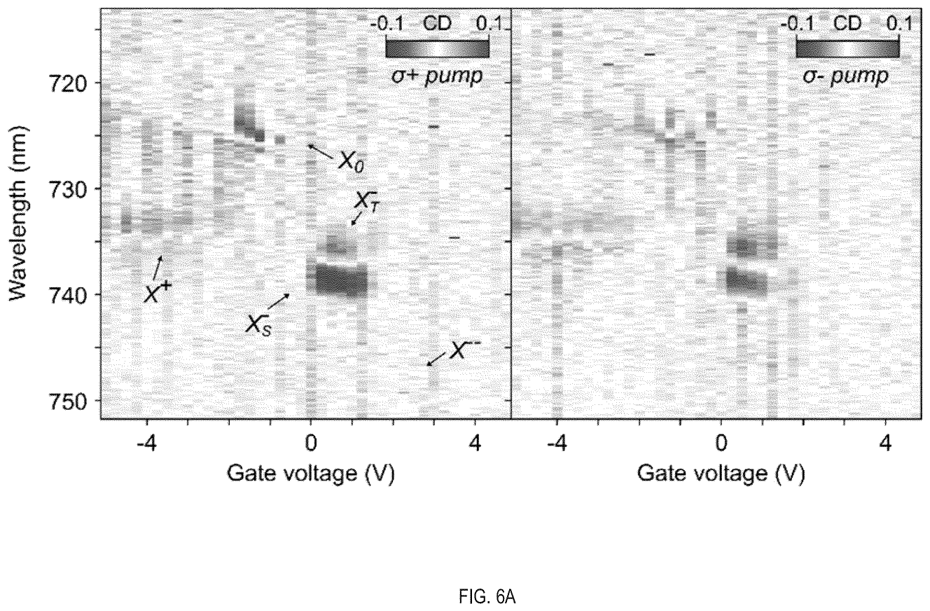

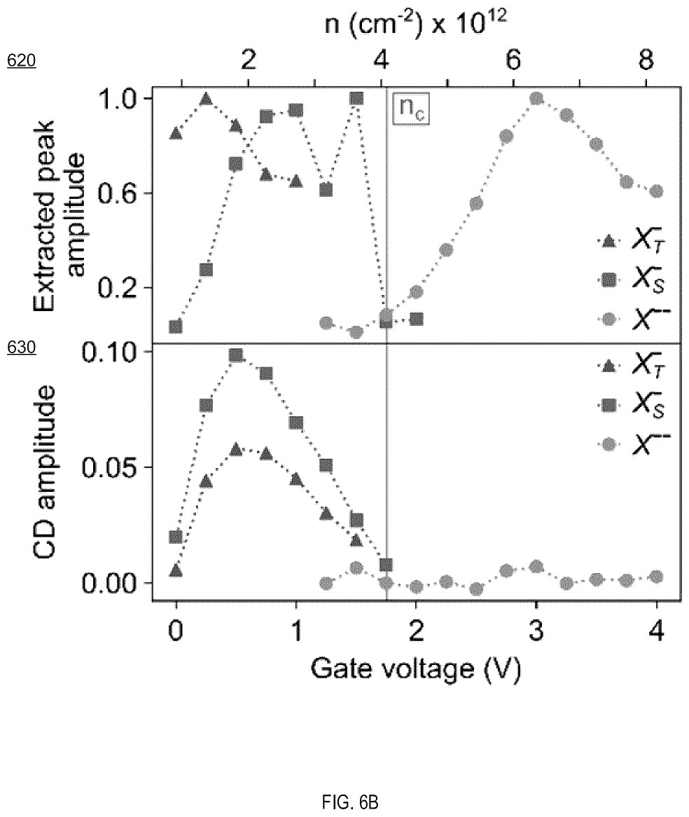

To gain additional insight into the origin of the mesoscopic CD, the doping concentration may be varied. As depicted in FIG. 4C, the intrinsic, hole-doped and highly electron-doped region may be assessed by varying the gate voltage. Here, the long-range CD (i.e., pump-probe separation of 8 μm, FIG. 4B) within these different doping regions may be studied. As shown in FIG. 6A, no CD signal is observed in the intrinsic region, implying the optically induced CD is correlated with free carriers in the system. Referring to 460 in FIG. 4D, strong CD co(cross)-polarized to the pump from the triplet (singlet) features may be observed. At higher doping concentrations, while the heavily-doped charged exciton X⁻⁻ (Mahan exciton or attractive polaron) is clearly observed in reflectivity, there may be no observable CD. It is further characterized by plotting the extracted peak amplitude (620 in FIG. 6B) and CD amplitude (630 in FIG. 6B) against the estimated doping density for different species of excitonic states. It is observed that at 1.75 V, n_{c}≈4×10¹² cm⁻², the system transitions from observable singlet and triplet trions with strong CD, to X⁻⁻ exciton states with no observable CD. Therefore, measurements clearly correlate the CD with the singlet and triplet trion spectral features in the electron-doped regime. CD signal in the hole-doped region may be also observed. It may be noted that in the hole-doped regime, it may be unable to fully quench the exciton reflectivity, indicating limited doping capability.

FIG. 6A and FIG. 6B describe gate dependence of CD spectra. FIG. 6A includes gate dependent CD spectra probed 8 um from the pump (FIG. 4B) under σ+ (left) and σ− (right) pumping. Excitonic states are labeled corresponding to the features in reflection spectra. 620 in FIG. 6B includes extracted peak amplitude versus gate voltage (doping level). 630 in FIG. 6B includes CD amplitude versus gate voltage (doping level). The critical electron density n_{c} is indicated. T=4 K and pump power is 7.8 μW.

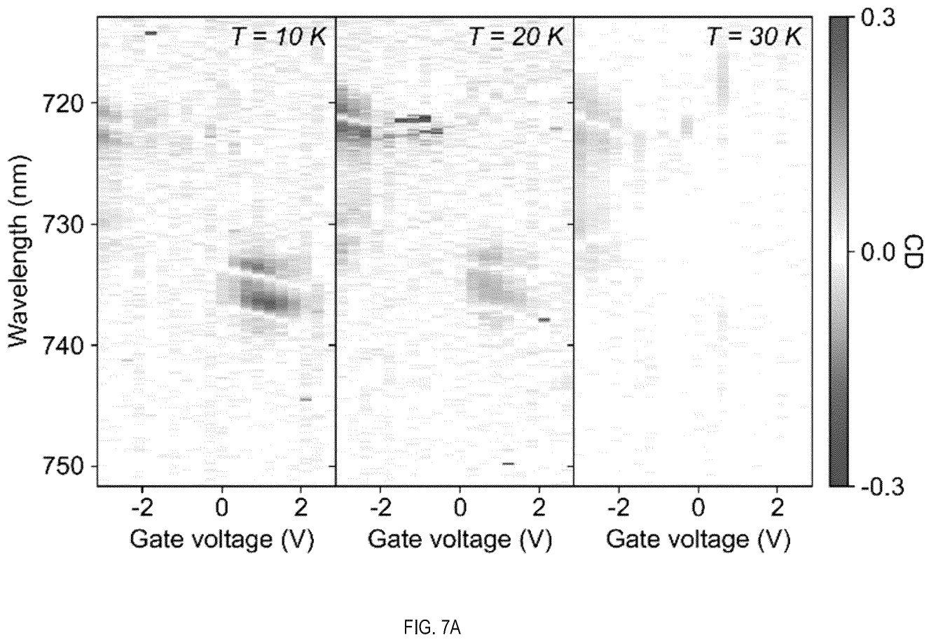

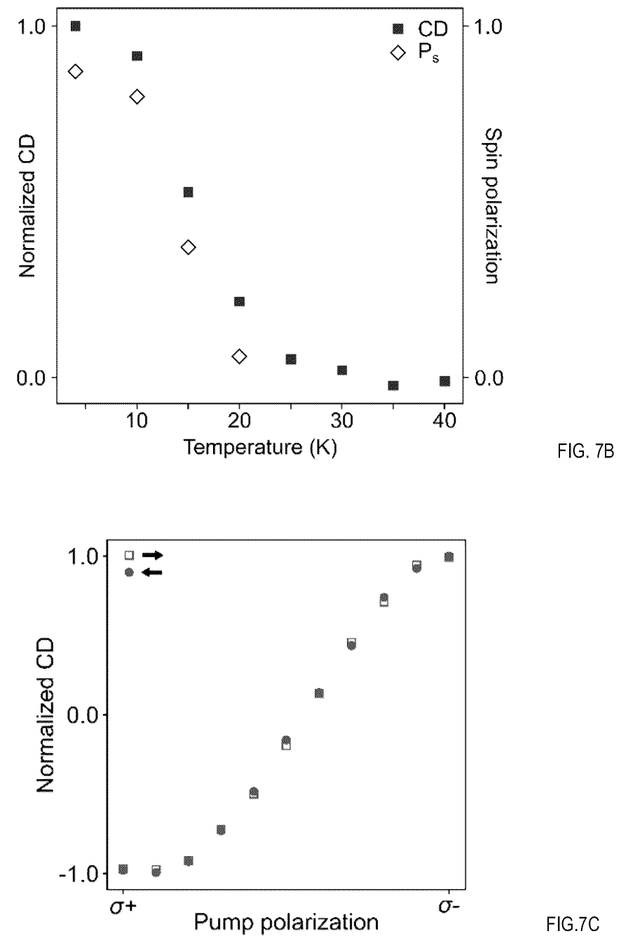

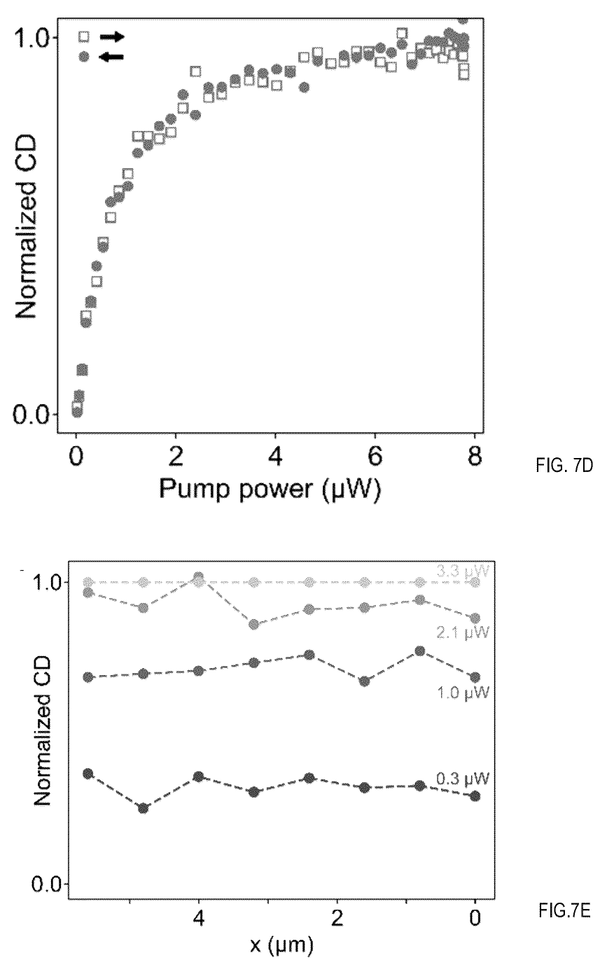

The present disclosure also investigates the strength of the CD with respect to changes in temperature (on a second exemplary device (D2)), pump polarization, and excitation power. FIG. 7A depicts the doping dependent CD spectra at different temperatures. The CD signal vanishes at T=30 K, even though reflection spectra still exhibit clear resonance features of singlet/triplet trions and X-states. The temperature dependent triplet CD amplitude and estimated spin polarization are plotted in FIG. 7B, showing a rapid transition from an unpolarized (Pₛ=0.06) to a polarized (Pₛ=0.87) spin state as the temperature goes below T=15 K. To gauge the impact of pump polarization on CD, the polarization may be swept from σ+ to linear and then σ− (FIG. 7C), observing the singlet CD signal increase from its minimum value through zero to its maximum value. When scanning in the opposite direction, the CD signal shows the same trend, vanishing at linear pump polarization. Lastly, the impact of pump power on CD (FIG. 7D) may be measured. The pump induces mesoscopic CD even with powers as low as 100 nW, and the CD signal begins saturating at ˜2 W. No hysteresis is observed when the pump power is scanned in the opposite direction, similar to the pump polarization scan. While the magnitude of the CD varies with pump power, the spatial profile of the CD remains nearly uniform within an order of magnitude variation in pumping power (FIG. 7E).

FIGS. 7A-7E describe stability of CD signal. FIG. 7A includes gate-dependent CD spectra of a second exemplary device (D2) at 10 K, 20 K and 30 K (pump-probe offset of 2.2 μm, pump power of 10 μW). FIG. 7B includes temperature dependence of triplet CD amplitude (red squares) selected from gate-dependent CD spectra at gate voltage of 1.2 V. Corresponding spin polarizations (hollow diamond) are extracted from reflection spectra. FIG. 7C includes polarization dependence of singlet CD amplitude of the exemplary device (D1) (pump-probe offset of 1.6 μm, pump power of 7.8 μW). Hollow squares (solid circles) correspond to sweeping the polarization from σ+ to σ− (σ− to σ+). FIG. 7D includes power dependence of singlet CD amplitude of the exemplary device (D1) (pump-probe offset of 1.6 μm). Hollow squares (solid circles) correspond to increasing (decreasing) pump power. FIG. 7E includes spatial dependence of singlet CD amplitude of the exemplary device (D1) under selected pump powers, normalized to the 3.3 μW profile. T=4 K unless otherwise stated.

### Mesoscopic Magnetic/spin States of 2DEGs

The mesoscopic spin polarization may be attributed to ferromagnetic order in the TMD induced by the optical pump. This claim is supported by the following observations: (I) In the measurements, mesoscopic spin-polarization emerges within the same carrier density regime as theoretically predicted and experimentally studied ferromagnetic phases in TMDs. In theoretical models of electron-electron interactions in TMDs, exchange inter-and intra-valley coupling lead to spin-polarized ferromagnetic phases at electron densities around nₑ˜10¹² cm⁻². These models were validated by experimental studies of magnetic phases in electron-doped monolayer molybdenum disulphide (MoS₂) in an external magnetic field. In that case, strong exchange intervalley interactions—compared to the small spin-orbit splitting of the conduction bands in MOS₂—lead to band inversion and the spin polarization of resident electrons across both K and K′ valleys (i.e., spin-polarized, but not valley-polarized electrons). In contrast, WSe₂ monolayers exhibit an order of magnitude larger spin-orbit splitting in the conduction band. Consequently, the predicted ferromagnetic ground state consists of spin/valley-polarized resident electrons, in agreement with the circular dichroism results. (II) The temperature dependence of the CD signal, which represents the magnetization, displays a trend qualitatively consistent with other 2D ferromagnetic materials, and criticality fits indicate a Curie temperature T_{C}=15 K with a critical exponent of 0.113, close to the value of 0.125 for a 2D Ising model. (III) The disappearance of spin polarization with increased electron doping signifies a 1^{st}-order phase transition from a ferromagnetic to a paramagnetic phase. This is in full agreement with other experimental and theoretical studies of magnetic phase transitions in TMDs. (IV) Signatures of long-range order in the hole-doped regime are observed, consistent with theory, although yet to be shown experimentally.

While spin diffusion and giant-paramagnetic order are alternative mechanisms for generating long-range spin polarization, the experimental data does not support these processes. There is no obvious correlation between the CD amplitude and the separation of the pump and probe, in stark contrast to a diffusion process. Additionally, the rapid and complete disappearance of long-range CD with relatively small changes in carrier density is not readily explained by simple diffusion. Furthermore, a magnetic field is not applied, eliminating the possibility of interaction-enhanced paramagnetic order. The temperature dependence also is incompatible with a paramagnetic phase, failing to maintain a 1/T trend at low temperature. In total, the experimental observations of mesoscopic spin polarization are fully consistent with the emergence and control of ferromagnetic order by optical pumping.

In some implementations, a continuous-wave optical pump may be used to break the symmetry between equivalent magnetic phases and stabilize mesoscopic magnetic order against fluctuations. Magnetic/spin state fluctuations explain both the absence of spin order below T_{c} without the optical pump and the lack of observable hysteresis in the time-averaged measurements. The fluctuations may arise due to nano-ampere-scale leakage currents in the exemplary device, which can destabilize the magnetic/spin state by injecting unpolarized electrons. The optical pump then stabilizes a single magnetic/spin state against fluctuations by selectively valley-pumping spin-polarized electrons, thereby breaking the symmetry between degenerate magnetic/spin states and preferentially favoring the formation of a co-polarized magnetic/spin state. This mechanism is fundamentally different from previously reported all-optical control of spin order, which is based on heating and inverse Faraday effects. It may be emphasized that the optical pump should not be considered directly analogous to an external magnetic field as a symmetry breaking mechanism. In contrast to Zeeman interaction in a magnetic field, the optical pump does not change the energetics of the system. Additionally, the dynamics of the pump-induced spin polarization may lead to time-dependent evolution of the magnetic phase, which is not captured by the steady state measurements.

In the present disclosure, while the optical pump acts locally at where the optical beam interacts with the 2DEGs, the magnetic order may be stabilized mesoscopically, extending well beyond the sub-micron pumping region to the boundaries of the monolayer. The measurements afford some insight into the nature of this non-locality. It may be observed that, rather than spreading from the pump location in a non-linear fashion, the spin order emerges uniformly over the exemplary device with increasing pump power. This suggests that in the absence of optical pumping, long-range magnetic phases exist in the exemplary device, but the phases fluctuate temporally between spin configurations. The optical pump acts to pin one of the two long-range magnetic phases against fluctuations. The micron-scale domain size in the measurements is comparable in size to magnetic domains in other 2D magnetic materials. This picture contrasts with a model in which the electronic ground state at zero applied magnetic field consists of local, nanoscale magnetic domains—in this picture, the pumping would not be expected to generate mesoscopic polarization beyond the locally controlled domains. Other studies may fully elucidate the dynamics of the magnetic phases and the process of long-range stabilization.

As such, ferromagnetic order in TMDs may be optically generated, maintained, and controlled. The recent discovery of magnetic 2D materials has generated significant excitement due to their novel integration and heterostructure possibilities. The present disclosure clearly establishes TMDs as a 2D magnetic material, albeit with very different properties than more conventional 2D magnets-critically, the magnetic configuration can be fully tuned non-locally with optical fields and electronic gating. Moreover, the local optical pump stabilizes the magnetic/spin state, even at low sub-microwatt power, providing finer spatial resolution for the study and control of magnetic domain structure. These unique features open new avenues for probing the previously inaccessible physics of magnetic order in two-dimensional semiconductors, prompting future experimental and theoretical investigations of the temporal dynamics and spatial formation of domains under optical pumping. Additionally, TMDs are a prototypical platform for explorations of correlated phenomena in 2DEGs, and it may be shown that optical pumps provide a powerful tool for understanding and controlling these systems. For instance, magnetic phases and their circular dichroism could be utilized to manipulate and probe Mott insulators and Wigner crystals.

The present disclosure above may enable and/or accelerate technological developments utilizing TMDs, already a leading material platform for investigating next-generation spin-, valley-, and optoelectronics. Specifically, the discovery of optically-reconfigurable spin order and circular dichroism in atomically thin semiconductors will stimulate the design of non-reciprocal optoelectronics and photonics, such as on-chip all-optical isolators with built-in optical memory. Lastly, the present disclosure may create a bridge between spin order and optical control in

TMDs, which can be leveraged for direct interfacing between integrated photonics and magnetic solid-state memories, suggesting new routes for neuromorphic optical computing.

### Example 2D Monolayer Device Fabrication

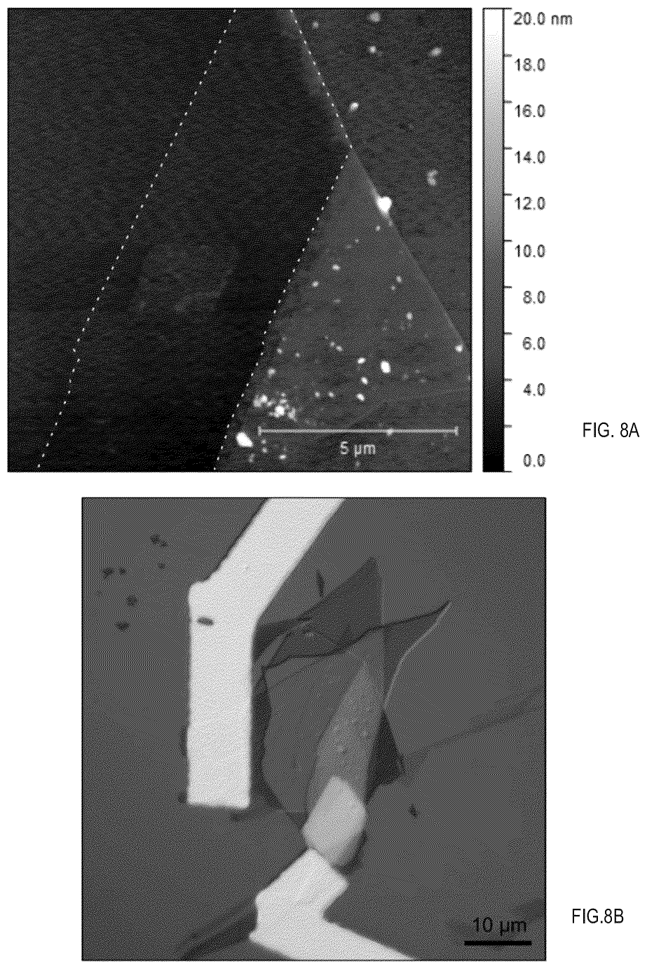

In various embodiments, the monolayer tungsten diselenide (WSe₂), hexagonal boron nitride (hBN) and few-layer graphene (FLG) flakes are mechanically exfoliated from commercial bulk crystal (WSe₂—2D Semiconductor; hBN and FLG-HQGraphene) onto Si/SiO₂ chips. The thickness and cleanliness of the flakes are first examined with optical microscopy and then by atomic force microscopy (AFM) (FIG. 8A). an all-dry transfer method may be used to fabricate the hBN-encapsulated WSe₂ stack with FLG top gate and contact. Electrodes are patterned via photolithography, and then deposited by e-beam physical deposition with 5 nm Ti and 95 nm Au (FIG. 8B). It may be noted that a second exemplary device (D2) has a layer of PMMA on top of the completed heterostructure.

FIGS. 8A-8B describes an exemplary device fabrication. FIG. 8A includes AFM image of the WSe₂ flake on Si/SiO₂ chip with monolayer region outlined. FIG. 8B includes optical microscope image of the full heterostructure D1 with patterned contacts.

### Example Optical Setup Configuration

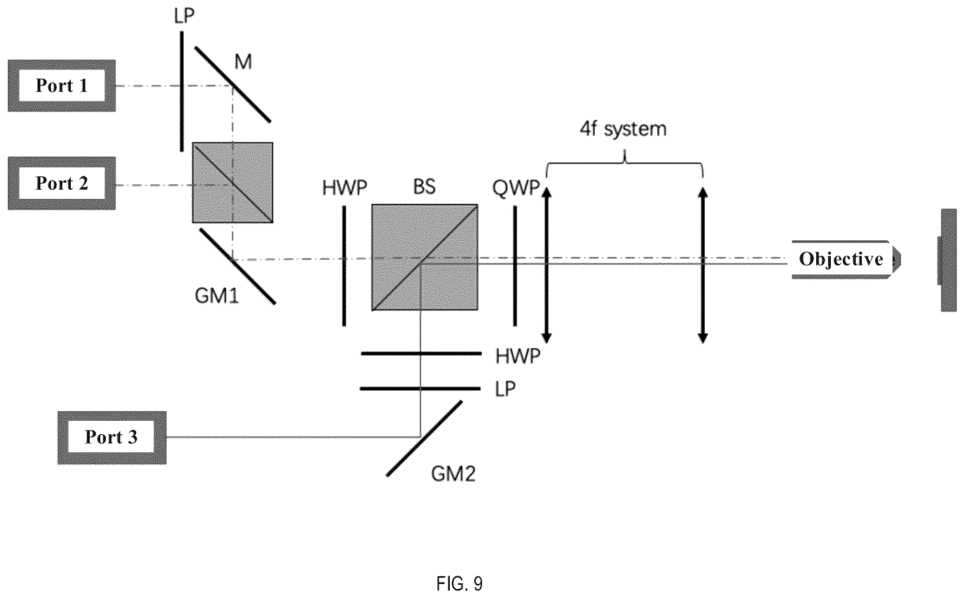

The example 2DEGs devices may be kept in a close loop cryostat (for example from a vendor of Montana Instruments) at 4 K during the experiment unless otherwise claimed. The optical setup is depicted in FIG. 9. The two galvo mirrors may control the pump and probe beam independently to realize spatial scans. A 660 nm diode laser (for example from a vendor of Thorlabs) may be used as the optical pump exciting through port 3 with a band pass filter to spectrally clean the pump laser. A supercontinuum laser (for example from a vendor of YSL Photonics) may be deployed as the broadband probe sent through port 1. The reflection of the supercontinuum from the device is collected by port 2 and fiber coupled to a spectrometer with CCD (for example from a vendor of Teledyne Princeton Instruments) to realize spectrally resolved reflection measurements. The polarizations of each beam are independently controlled by linear polarizers and half-wave plates to allow different pump/probe polarization combinations.

To map the photoluminescence (PL) from the exemplary device (FIG. 5A), ports 1 and 2 may be used as the pump and collection channels, respectively. The same 660 nm diode laser is used for pumping. The PL signal is collected from port 2 and detected by an APD (for example from a vendor of Excelitas). By scanning galvo mirror 1, the co-localized pump and collection are simultaneously moved across the exemplary device, realizing the PL mapping.

FIG. 9 shows optical setup. Setup components are: Port-fiber launcher, M—mirror, GM—Galvo mirror, LP—linear polarizer, HWP—half-wave plate, QWP—quarter-wave plate, BS—beam splitter, 4f system—lens pair, objective−NA=0.75.

### Capacitor Model of Charge Density Estimation

To estimate the charge carrier density under electrostatic gating, the heterostructure may be modeled as a parallel plate capacitor. The FLG and monolayer WSe₂ flakes are the electrodes separated by the dielectric top hBN flake. The capacitance per unit area is given by

$$C = \frac{{ϵ}_{h B N} {ϵ}_{0}}{{d}_{h B N}} .$$

Using the relative permittivity of hBN ϵ_{hBN}=3.76 and the hBN thickness d_{hBN}=11.5 nm, it may be found that C≈290 nF cm⁻². The carrier density as a function of gate voltage is given by n(V_{g})=C(V_{g}−V₀), where V₀ is the gate voltage corresponding to the intrinsic regime with no carrier doping. By comparison with the neutral exciton feature in reflection (FIG. 1c), it may be approximated that V₀=−0.5 V.

### Line Shape Analysis

To estimate the valley/spin polarization of the free carriers, the total oscillator strength of the trions in the two valleys may be extracted. By comparing the oscillator strengths, the relative density of states in each valley may be approximated, which give an estimation of the polarization of the free carriers.

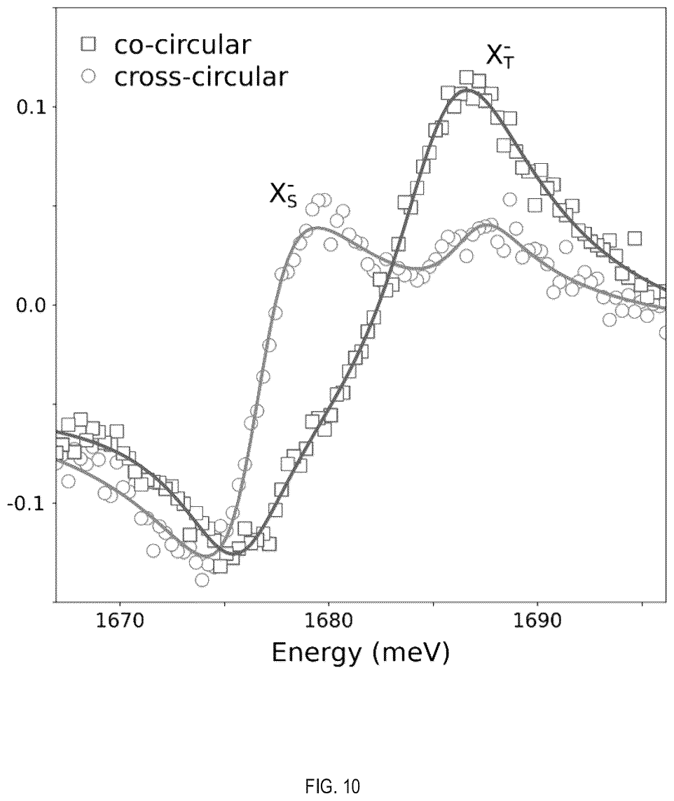

The reflection contrast corresponding to the two trion features from 450 in FIG. 4D is depicted in FIG. 10 (dots), which shows an asymmetric Fano-like line shape. The reflection contrast is given by

$$R C = \frac{R}{{R}_{ref}} - 1 ,$$

where R is the bare reflectivity (see 450 in FIG. 4D) and R_{ref} is a reference reflectivity where the trion oscillator strengths disappear, under large gate bias or in the intrinsic region. Such spectra can be captured by a two-peak Breit-Wigner-Fano (BWF) line shape fitting:

$$I ( ω ) = {I}_{1} \frac{{( 1 + \frac{ω - {ω}_{1}}{{q}_{1} {Γ}_{1}} )}^{2}}{1 + {( \frac{ω - {ω}_{1}}{{Γ}_{1}} )}^{2}} + {I}_{2} \frac{{( 1 + \frac{ω - {ω}_{2}}{{q}_{2} {Γ}_{2}} )}^{2}}{1 + {( \frac{ω - {ω}_{2}}{{Γ}_{2}} )}^{2}} + C$$

where q_{1/2} is the parameter which captures the asymmetry of the line shape. When

$$\frac{1}{q} \to 0 ,$$

the function converges to the Lorentzian line shape, where I_{1/2} is the amplitude, Φ_{1/2} is the center energy, and Γ_{1/2} is the linewidth.

By fitting the RC to a superposition of BWF line shapes with two resonances corresponding to the singlet and triplet trions (FIG. 10, lines), The fitting parameters shown in Table 1 are extracted. The oscillator strength of each resonance is proportional to the area of the Lorentzian line shape A=I₀Γ. By comparing the relative oscillator strengths for each state under co- and cross-circular pumping, the ratio of the density of states in each valley can be estimated. This ratio, 90:10 for the triplet trion, is taken as the ratio between the valley-polarized spin states of the resident electrons. By similarly fitting pump-off RC spectra, balanced detection gives a polarization sensitivity as low as 3%.

FIG. 10 shows line shape fitting. Polarized reflection contrast spectra showing singlet (X_{S}_{^{−}}) and triplet (X_{T}_{^{−}}) trion features under optical pumping. The pink (blue) dots correspond to the probe being polarized co- (cross-) circular to the pump. BWF fittings are plotted.

TABLE 1
Fitting the trion features under optical pumping

| | I₀ | ω₀ (meV) | Γ (meV) | A = I₀Γ | Ratio | Pₛ |
|---|---|---|---|---|---|---|
| Triplet | | | | | | |
| Co-circular | 0.151 | 1685.4 | 4.1 | 0.62 | ~90:10 | 0.77 |
| Cross- | 0.035 | 1687.0 | 2.3 | 0.08 | | |
| circular | | | | | | |
| Singlet | | | | | | |
| Co-circular | 0.0005 | 1675.8 | 3.3 | 0.0016 | ~99:1 | −0.98 |
| Cross- | 0.075 | 1676.5 | 2.7 | 0.20 | | |
| circular | | | | | | |

### Another Exemplary Device Characterization and Temperature Dependence

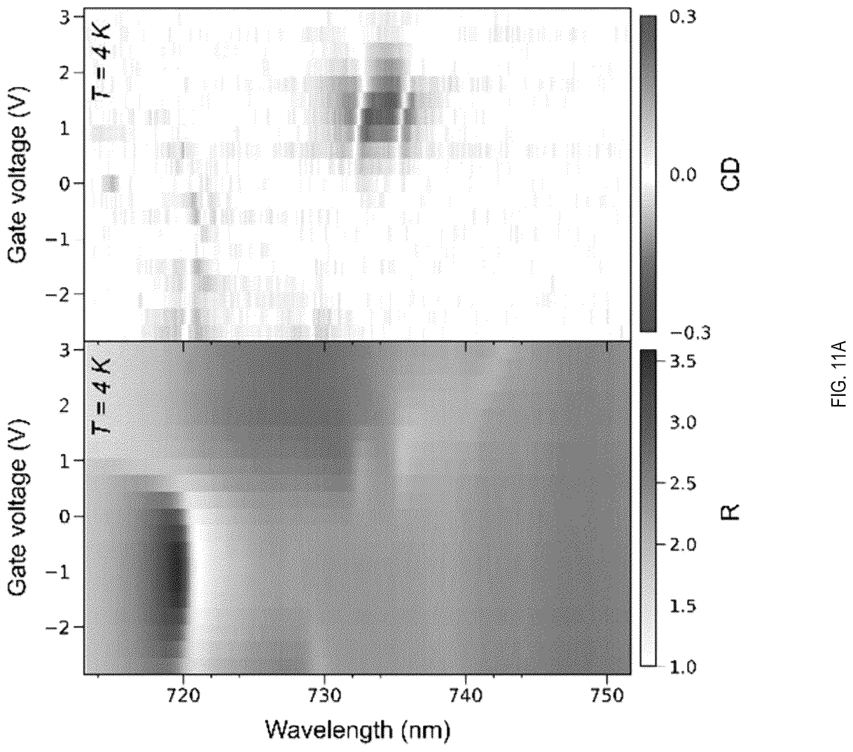

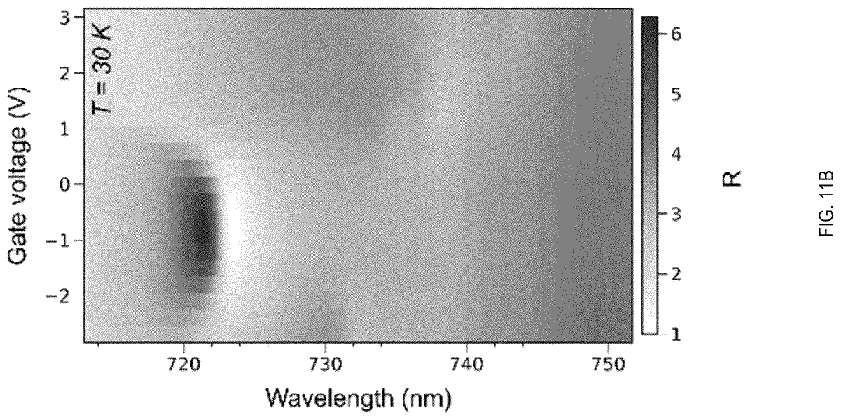

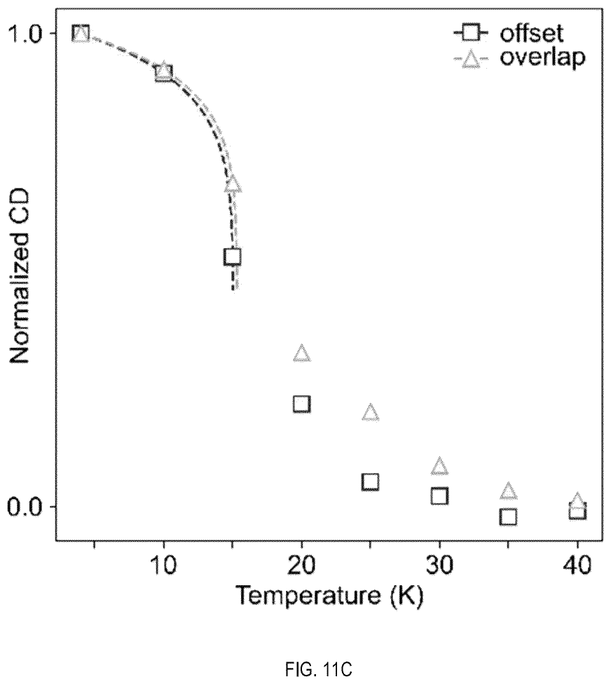

The temperature-dependent measurements (FIGS. 7A and 7B) are performed on a second exemplary device (D2). FIG. 11A shows gate-dependent reflection spectra at 4 K with a pump-probe separation of 2.2 μm, which display similar doping regimes as the exemplary device (D1) (FIG. 4C). In the electron-doped region, strong CD signal is observed. FIG. 11B depicts the reflection spectra at 30 K. While the electron-doped CD vanishes at this elevated temperature (FIG. 7A), the singlet and triplet trion features remain, confirming that the temperature dependence of the CD signal probes that of the spin polarization. Temperature dependent data was also taken with overlapped pump and probe. The CD amplitude shows a very similar trend as that with a 2.2 μm pump-probe offset (FIG. 11C). The criticality fit α(T_{c}−T)^{β} is applied to the CD data, extracting a critical temperature T_{c}=15.0 K (15.3 K) and a critical exponent β=0.113 (0.106) for the offset (overlapping) pump-probe configuration. For the 2D Ising model, the expected critical exponent is β=0.125.

FIGS. 11A-11C show a second exemplary device (D2) characterization. FIG. 11A includes gate-dependent reflection (left) and CD spectra (right) at 4 K with a pump-probe separation of 2.2 ρm. FIG. 11B includes reflection spectra at 30 K. FIG. 11C includes temperature dependence of triplet CD amplitude selected from gate-dependent CD spectra at gate voltage of 1.2 V. Hollow squares (triangles) correspond to experimental data for offset (overlapping) pump and probe with respective fittings (dashed lines).

### Another Device Characterization and Comparison of Temporal Dynamics With Diffusion

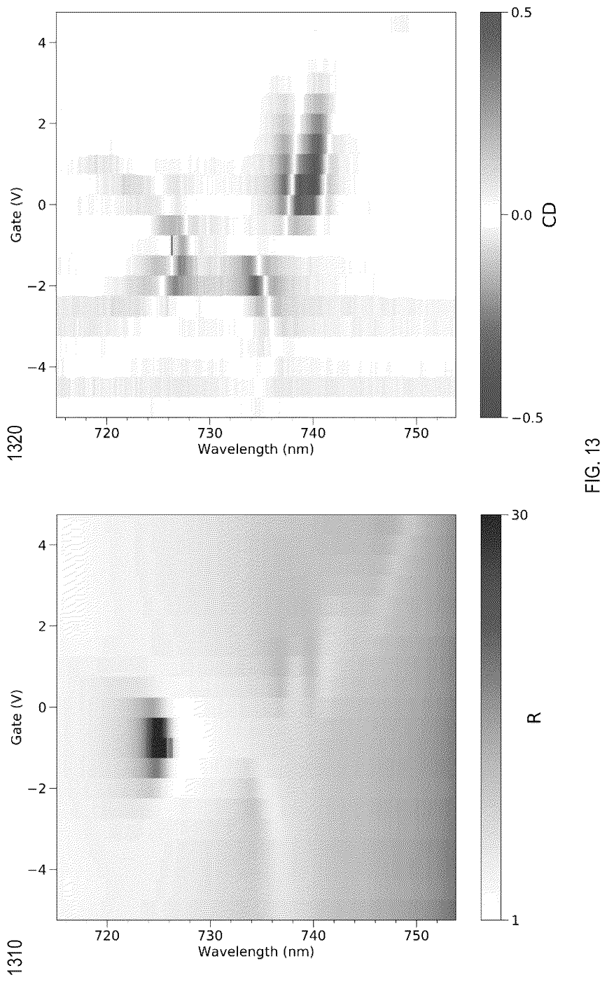

The temporal dynamics are measured on a different device. Characteristic reflection spectra and CD spectra are shown in FIG. 13. Using the time-resolved, circularly polarized differential reflection measurement results at selected positions with different distances from the pump, the temporal profile is compared with that predicted in a diffusion picture. FIG. 13 shows a gate-dependent reflection (1310) and CD spectra (1320) at 4 K with a pump-probe separation of 3 μm and pump power of 7.8 μW.

The spin polarization under pulsed pumping is extracted from the differential reflection in the CW pumping case:

$${P}_{s}^{p u l s e} ( t ) = \frac{Δ {R}^{p u l s e} ( λ , t )}{Δ {R}^{CW} ( λ )} {P}_{s}^{CW}$$

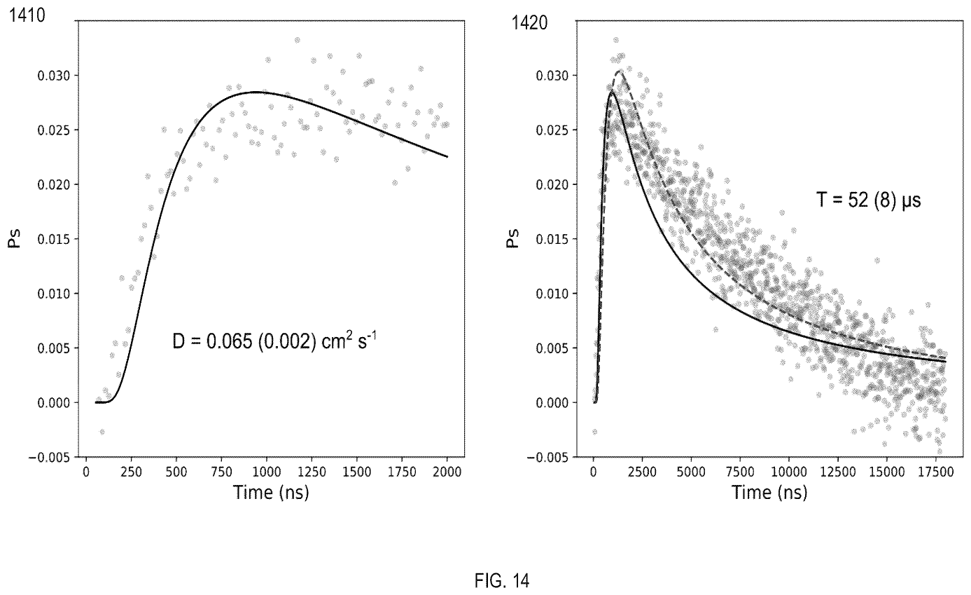

P_{S}^{CW} is the spin polarization found from the line shape analysis of the oscillator strength transfer under CW pumping. ΔR^{pulse/CW} is the differential reflection at wavelength of interest λ under pulsed/CW pumping. A clear build-up process is measured as a rising edge in the time resolved measurements as shown in 1410 in FIG. 14 for a pump-probe separation of 4.87 μm. Thus, the temporal profile may be tentatively fit with a two-dimensional diffusion-decay model:

$${P}_{s} ( x , t ) = \frac{\begin{matrix}{σ}_{0}^{2} & {P}_{s}^{0}\end{matrix}}{{σ}_{0}^{2} + 4 D t} {e}^{- {x}^{2} / ( {σ}_{0}^{2} + 4 Dt )} {e}^{- t / T}$$

where D is the diffusion constant, T is the spin polarization lifetime, and σ₀=0.78 μm is the spatial convolution of the pump and probe beam sizes.

While the fitting cannot accurately capture the full temporal evolution of the spin profile (1420 in FIG. 14), the diffusion constant extracted by fitting the rising edge (1410 in FIG. 14) provides an estimate of ˜0.065 cm² s⁻¹ for the propagation speed of the spin order formation. This value is significantly lower than the measured diffusion constant in previous research, indicating a different mechanism behind the spin order propagation. The decay trend gives a spin lifetime of ˜52 μs (1420 in FIG. 14).

FIG. 14 shows time resolved measurement for point 4.78 μm away from pump. 1410 shows a rising edge profile with two-dimensional diffusion-decay model fitting (black line). 1420 shows that fitting the full-time range with D=0.065 cm² s⁻¹ from the rising edge (black solid line) fitting yields lifetimes beyond a second (i.e., no decay). Fitting both D and T (blue dashed line) yields D=0.045 cm² s−1 and T=52 μs. Fitting uncertainties are in parentheses. T=4 K, average pump power is 2 nW at a repetition rate of 50 kHz, and gate voltage is 0.5 V (nₑ˜2×10¹² cm⁻²).

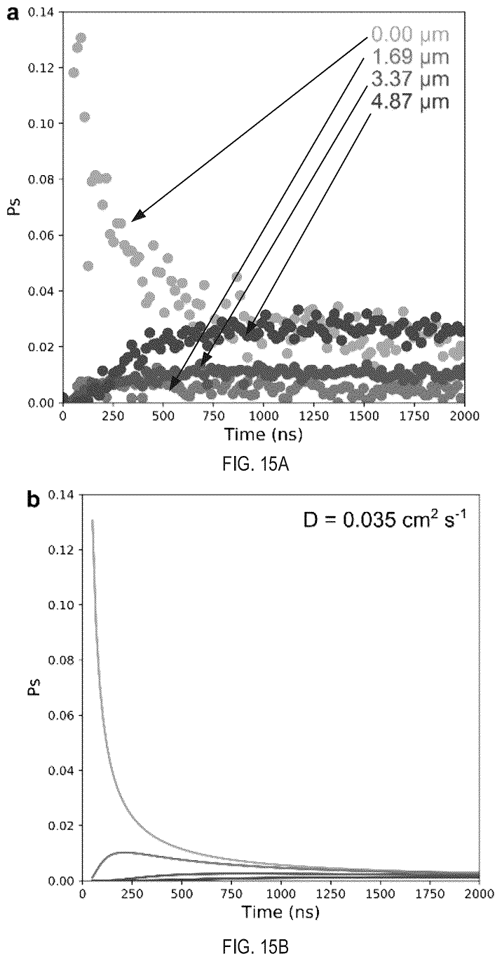

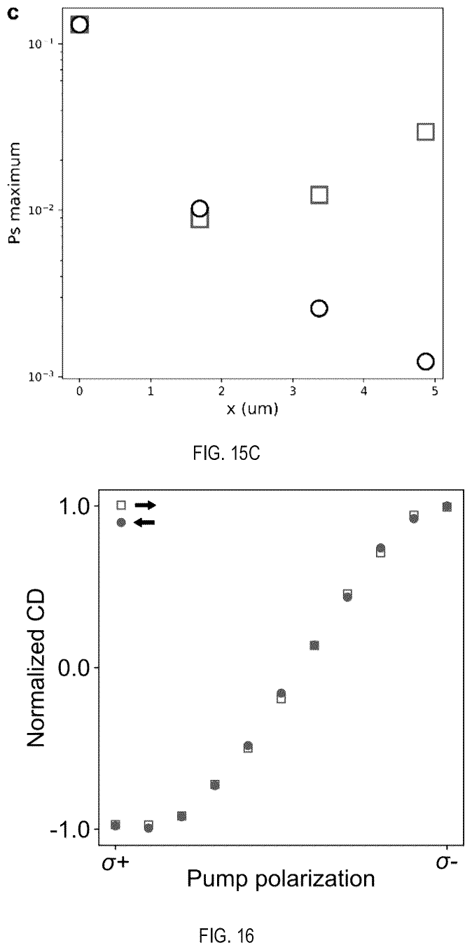

The measured temporal profiles for various pump-probe separations with those of the diffusion model are compared (FIGS. 15A-15C). Ignoring decay, diffusive transport of a fixed number of spins away from a local source should lead to an approximately 1/r² dependence in the peak polarization measured a distance r from the source. This geometric constraint suggests a rapid fall off in the maximum spin polarization away from the pump, as seen in FIG. 15B for a diffusion model with representative D=0.035 cm² s⁻¹ and infinite lifetime. In contrast, the measured maximum polarization shows no systematic change as the offset varies, even increasing at larger distances (FIG. 15A). The measured spin polarization is amplified by almost an order of magnitude compared to purely diffusive propagation (FIG. 15C). The variations in maximum polarization can be attributed to local deviations in the dielectric environment or defects distributed across the sample. The strength of the electron-electron interactions, which creates the ferromagnetic state, will vary throughout the sample due to these inhomogeneities. Correspondingly, the maximum spin polarization will also vary.

FIG. 15 shows additional time resolved data. FIG. 15A sows time resolved measurement for different pump-probe separations. FIG. 15B shows simulation of diffusion model with diffusion constant D=0.035 cm² s⁻¹ for different separations. FIG. 15C shows comparison between the measured (squares) and simulated (circles) maximum spin polarization. T=4 K, average pump power is 2 nW at a repetition rate of 50 kHz, and gate voltage is 0.5 V (nₑ˜2×10¹² cm⁻²).

### Hysteresis Check

In addition to sweeping the pump power, magnetic hysteresis may be examined by continuously varying the pump polarization in opposite directions. No observable hysteresis loop is observed (FIG. 16). Similarly, previous measurements in monolayer MoS₂ do not observe hysteresis under an applied magnetic field.

FIG. 16 shows Pump polarization sweep. Polarization dependence of singlet CD amplitude. Hollow squares (solid circles) correspond to sweeping the polarization from σ+ to σ− (σ− to σ+). T=4 K, pump power is 7.8 μW, pump-probe offset is 1.6 μm, and gate voltage is 0.5 V (nₑ˜2×10¹² cm⁻²).

### Another Device Characterization and Comparison of Temperature- and Gate-Dependent Results With Steady-State Diffusion

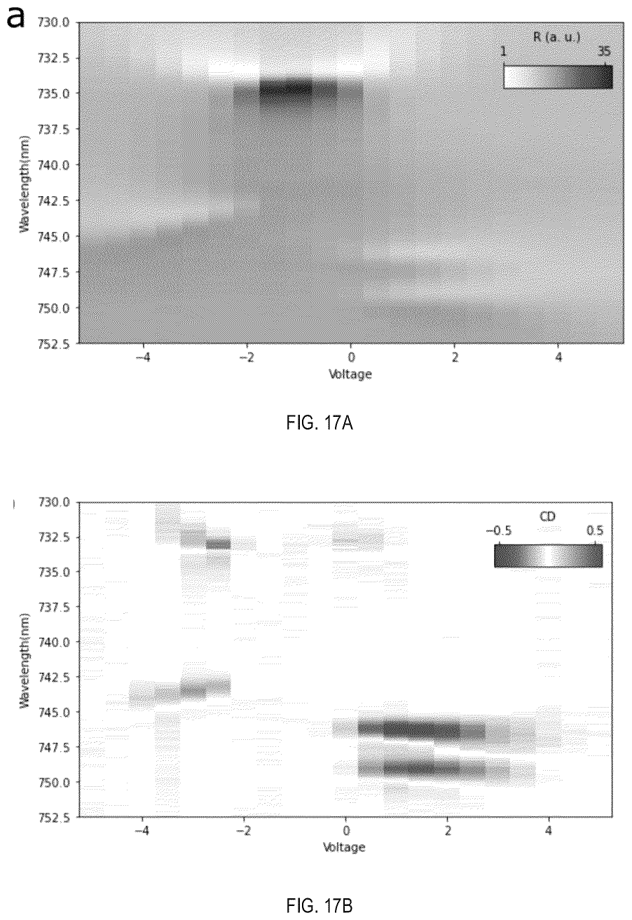

Predictions of the spin diffusion model under CW pumping are tested against additional experimental data taken from another device. FIGS. 17A and 17B show characterization of another device, wherein FIG. 17A shows gate-dependent reflection and FIG. 17B shows CD spectra at 4 K with a pump-probe separation of 2.5 μm and pump power of 7.8 μW.

Temperature and doping dependence of the CD spatial profile. The spin lifetime of electrons may be strongly dependent on the temperature and doping level. In a simple diffusion model the spin diffusion length is directly correlated with the spin lifetime. Thus, within the diffusion model, the spatial profile of the CD signal would have a strong temperature and doping dependence. In FIG. 10, the spatial profiles of the CD signal at varying temperatures and doping levels are shown. The CD profiles uniformly decrease by an order of magnitude with no observable spatial contraction at elevated temperatures or increased doping. Thus, the observation is in stark contrast to the predictions of the diffusion model.

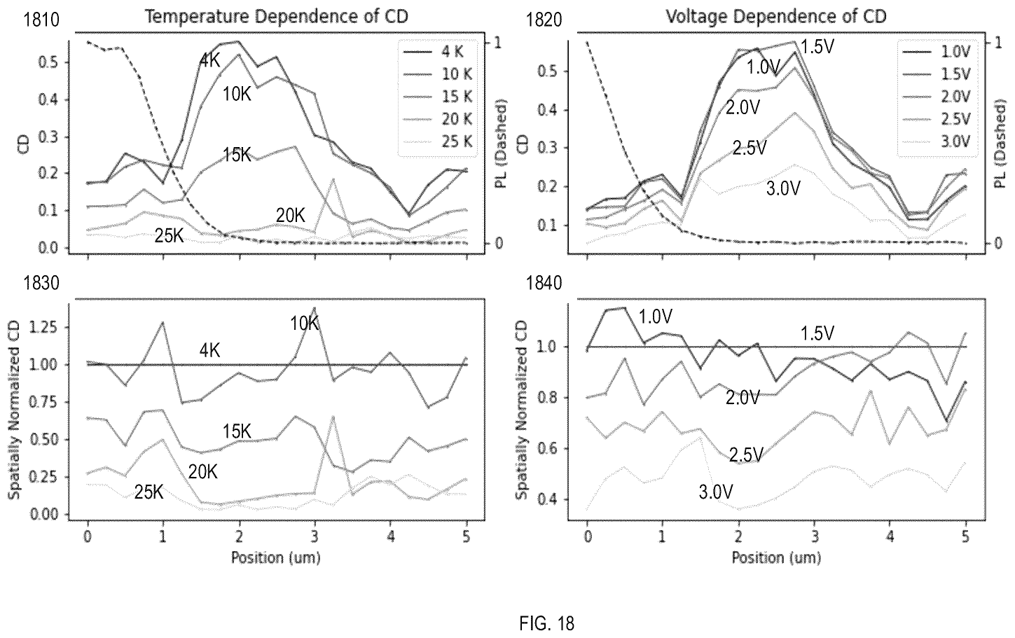

FIG. 18 shows temperature and gate dependence of CD spatial profiles. Measured (1810) and normalized (to 4 K) (1820) CD spatial profiles observed at various temperatures with a fixed gate voltage of 1.5 V (nₑ˜2.8×10¹² cm⁻²). Measured (1830) and normalized (to 1.5 V) (1840) CD spatial profiles observed at various gate biases (nₑ from ˜2×10¹² cm⁻² to ˜4×10¹² cm⁻²) with a fixed temperature of 4 K. Dashed line indicates the PL intensity, as guidance of pumping spot profile. The pump power is 7.8 μW.

Power saturation curves under different temperatures. In a spin pumping model with a CW laser, the steady state spin polarization results from competition between the spin pumping rate and the spin decay rate. Within this model, if the spin decay rate increases at increasing temperature, the loss of spin polarization could be compensated by increasing the pumping rate. This can be understood with simple rate equations for a single pump in the K valley:

$$\begin{matrix}\frac{d {N}_{+}}{d t} = - G {N}_{+} - γ ( {N}_{+} - {N}_{-} ) \\ \frac{d {N}_{-}}{d t} = G {N}_{+} - γ ( {N}_{-} - {N}_{+} )\end{matrix}$$

wherein N₊₍₋₎ are the number of electrons in the K (K′) valley, G is the spin pumping rate which is linear to the pumping power, and γ is the intervalley scattering (spin decay) rate. The steady state under CW pumping will have a spin polarization of:

$$\frac{{N}_{+} - {N}_{-}}{{N}_{+} + {N}_{-}} = - \frac{1}{1 + \frac{2 γ}{G}}$$

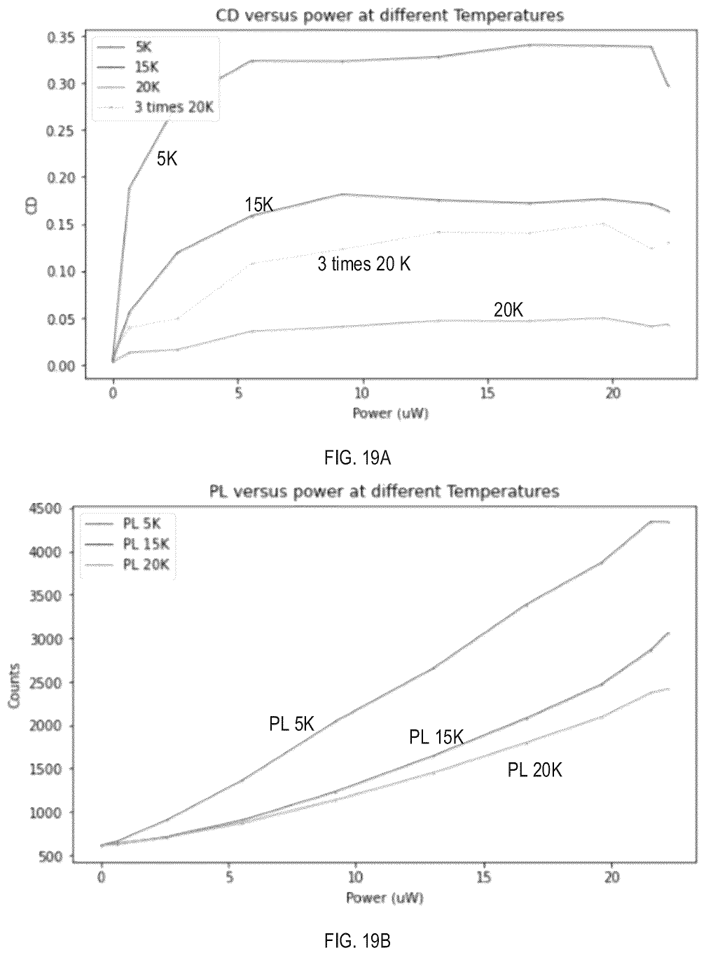

Within this model, the spin polarization should always saturate at a value of 1, as increases in the spin decay rate can always be offset by increasing the pump power-in other words, the saturated spin polarization should be largely temperature independent. To test this prediction, power-dependent CD signal under different temperatures are measured. As depicted in FIG. 19A, the CD signal saturates at similar powers, while the saturated CD amplitude decreases by an order of magnitude. The photoluminescence (PL) power dependence (FIG. 19B) indicates that the pumping is within the linear absorption regime, meaning the simple rate model should still hold. The saturated CD, then, is solely determined by the temperature. This directly contradicts the predictions of a simple spin pumping model. Such phenomena, on the other hand, is predicted by the temperature curve with a 2D magnetic order as discussed in the main text.

FIGS. 19A and 19B show power dependence of CD and PL amplitudes under different temperatures. Power-dependent CD with a pump-probe separation of 1.8 μm (FIG. 19A) and PL (FIG. 19B) amplitudes. Gate voltage is 1.5 V (nₑ˜2.8×10¹² cm⁻²), and pump power is 7.8 μW.

To summarize, a spin diffusion picture predicts dramatically decreasing of spin polarization under pulse pumping away from the pump and the spatial distribution should strongly depend on temperature and doping level. In contrast, the measurements show spin polarization significantly larger than the prediction, and with no observable temperature and doping dependence of the spatial profile, only the magnitude of the CD. Also, the power dependent CD amplitude curve under different temperatures significantly deviates from the prediction of the spin pumping/diffusion picture. Given the inadequacy of such a spin pumping/diffusion model to explain the complete dataset, magnetic interactions must account for the observation of long-range spin polarization generated by an optical pump.

While the particular disclosure has been described with reference to illustrative embodiments, this description is not meant to be limiting. Various modifications of the illustrative embodiments and additional embodiments of the disclosure will be apparent to one of ordinary skill in the art from this description. Those skilled in the art will readily recognize that these and various other modifications can be made to the exemplary embodiments, illustrated and described herein, without departing from the spirit and scope of the present disclosure. It is, therefore, contemplated that the appended claims will cover any such modifications and alternate embodiments. Certain proportions within the illustrations may be exaggerated, while other proportions may be minimized. Accordingly, the disclosure and the figures are to be regarded as illustrative rather than restrictive.

1. A device for controlling mesoscopic spin order of electrons, the device comprising:
a two-dimensional (2D) semiconductor monolayer configured to accommodate a 2D electron gas; and
a first receptacle configured to receive a first optical beam,
wherein:
the first optical beam is configured to interact with the 2D electron gas at a first in-plane spatial position to generate a mesoscopic spin state of electrons in the 2D semiconductor monolayer in absence of an external magnetic field.

2. The device according to claim 1, further comprising:
a second receptacle configured to receive a second optical beam, wherein:
the second optical beam is configured to probe the mesoscopic spin state of the electrons in the 2D electron gas at a second in-plane spatial position to generate a reflected optical beam, and
the first in-plane spatial position is different from the second in-plane spatial position; and
an output port configured to output the reflected optical beam to an optical detector, wherein the optical detector is configured to detect a reflectivity of the second optical beam by the 2D electron gas by measuring the reflected optical beam.

3. The device according to claim 2, wherein:
the first optical beam is tuned to a first energy larger than a bandgap of the 2D semiconductor monolayer; and
the second optical beam is tuned to a second energy resonant with at least one of an excitonic state, a singlet trion state, or a triplet trion state of the 2D electron gas.

4. The device according to claim 2, wherein:
the first optical beam is in a first polarized state.

5. The device according to claim 4, wherein:
in response to the second optical beam being in the first polarized state, a first reflectivity is obtained;
in response to the second optical beam being in a second polarized state, a second reflectivity is obtained, wherein the first polarized state is orthogonal to the second polarized state; and
a polarization dichroism is obtained as a measurement of the mesoscopic spin state of the electrons in the 2D semiconductor monolayer based on the first reflectivity and the second reflectivity.

6. The device according to claim 5, wherein:
the first polarized state is a left circular polarized state;
the second polarized state is a right circular polarized state; and
the polarization dichroism is a circular dichroism.

7. The device according to claim 1, wherein:
the first optical beam is a pulsed optical beam configured to inject a spin polarization in the 2D semiconductor monolayer.

8. The device according to claim 1, further comprising:
a top layer and a bottom layer sandwiching the 2D semiconductor monolayer; and
an electrically conductive layer disposed on the top layer and configured to generate an electrical field across the 2D semiconductor monolayer.

9. The device according to claim 8, wherein:
the 2D semiconductor monolayer comprises a tungsten diselenide (WSe₂) monolayer;
the top layer comprises a hexagonal boron nitride (hBN) layer;
the bottom layer comprises a hBN layer; and
the electrically conductive layer comprises a few-layer graphene (FLG).

10. The device according to claim 8, wherein:
the electrically conductive layer is electrically biased to control a density of the 2D electron gas.

11. The device according to claim 1, wherein:
the 2D electron gas is further configured to interact with a third optical beam to modify the mesoscopic spin state.

12. A method for controlling mesoscopic spin order of electrons, the method comprising:
providing a structure comprising a two-dimensional (2D) semiconductor monolayer configured to provide a 2D electron gas; and
applying a first optical beam to interact with the 2D electron gas at a first in-plane spatial position to generate a mesoscopic spin state of electrons in the 2D semiconductor monolayer in absence of an external magnetic field.

13. The method according to claim 12, further comprising:
applying a second optical beam to probe the mesoscopic spin state of the electrons in the 2D electron gas at a second in-plane spatial position to generate a reflected optical beam; and
detecting a reflectivity of the 2D electron gas at the second in-plane spatial position by measuring the reflected optical beam,
wherein the first in-plane spatial position is different from the second in-plane spatial position.

14. The method according to claim 13, wherein:
the first optical beam is tuned to a first energy larger than a bandgap of the 2D semiconductor monolayer; and
the second optical beam is tuned to a second energy resonant with at least one of a excitonic state, a singlet trion state, or a triplet trion state of the 2D electron gas.

15. The method according to claim 13, wherein:
the first optical beam is in a first polarized state.

16. The method according to claim 15, further comprising:
in response to the second optical beam being in the first polarized state, obtaining a first reflectivity;
in response to the second optical beam being in a second polarized state, obtaining a second reflectivity, wherein the first polarized state is orthogonal to the second polarized state; and
obtaining a polarization dichroism as a measurement of the mesoscopic spin state of the electrons in the 2D semiconductor monolayer based on the first reflectivity and the second reflectivity, wherein:
the first polarized state is a left circular polarized state;
the second polarized state is a right circular polarized stat; and
the polarization dichroism is a circular dichroism.

17. The method according to claim 12, wherein:
the first optical beam is a pulsed optical beam configured to inject a spin polarization in the 2D semiconductor monolayer.

18. The method according to claim 12, wherein the structure comprises:
a top layer and a bottom layer sandwiching the 2D semiconductor monolayer; and
an electrically conductive layer disposed on the top layer and configured to generate an electrical field across the 2D semiconductor monolayer, wherein:
the 2D semiconductor monolayer comprises a tungsten diselenide (WSe₂) monolayer;
the top layer comprises a hexagonal boron nitride (hBN) layer;
the bottom layer comprises a hBN layer; and
the electrically conductive layer comprises a few-layer graphene (FLG).

19. The method according to claim 18, wherein:
the electrically conductive layer is electrically biased to control a density of the 2D electron gas.

20. The method according to claim 12, further comprising:
applying a third optical beam to interact with the 2D electron gas to modify the mesoscopic spin state.
